(19) United States
(12) Patent Application Publication
(10) Pub. No.: US 2019/0081167 A1
(43) Pub. Date: Mar. 14, 2019

(54) NITRIDE SEMICONDUCTOR DEVICE

(71) Applicant: Wavetek Microelectronics Corporation, HSINCHU COUNTY (TW)

(72) Inventors: Chih-Yen Chen, Tainan City (TW); Hsien-Lung Yang, Taipei City (TW)

(21) Appl. No.: 15/820,404

(22) Filed: Nov. 21, 2017

(30) Foreign Application Priority Data
Sep. 8, 2017 (TW) 106130779

(51) Int. Cl. H01L 29/778; H01L 29/20; H01L 29/205; H01L 29/417; H01L 29/45; H01L 29/423; H01L 29/51; H01L 23/31; H01L 23/29; H01L 29/66; H01L 21/02; H01L 21/3115

(52) U.S. Cl. CPC H01L 29/7787; H01L 21/31155; H01L 29/205; H01L 29/41758; H01L 29/452; H01L 29/42364; H01L 29/517; H01L 29/518; H01L 23/3171; H01L 23/291; H01L 29/42372; H01L 29/66462; H01L 21/0254; H01L 21/02458; H01L 21/02178; H01L 29/2003

(57) ABSTRACT

A nitride semiconductor device is disclosed. A substrate is provided. A nitride semiconductor layer is disposed on the substrate. An AlN anode dielectric layer is disposed on the nitride semiconductor layer. An anode metal layer is disposed on the AlN anode dielectric layer. A fluorinated region is disposed in the AlN anode dielectric layer. The fluorinated region extends into the nitride semiconductor layer.

### BACKGROUND OF THE INVENTION

### 1. Field of the Invention

The present invention generally relates to a field of semiconductor technology. More particularly, the present invention relates to a nitride semiconductor device including a fluorinated anode structure and a method of fabricating the same.

### 2. Description of the Prior Art

The development of gallium nitride (GaN) power transistors is focused on normally-off operation and compatibility with driver integrated circuits (IC). Fluorine-plasma treatment and gate-recess processes have shown their abilities of meeting with the above mentioned requirements. However, the threshold voltage is usually limited to be below 1.5V, which lacks safety operation margin for practical circuit applications. By combining partial AlGaN barrier recess and multilayer fluorinated Al₂O₃ gate dielectric, a threshold voltage as high as 6.5V has been achieved. Nevertheless, the direct plasma treatment (fluorine and/or argon) onto the Al₂O₃ dielectric causes damage to the thin-film compactness and gate controllability, leading to the degradations of gate leakage current (>1E-08 A/mm), drain current capability (<600 mA/mm), and transconductance (<40 mS/mm).

An alternative method to implement fluorinated Al₂O₃ gate dielectric by in situ doping of fluorine with atomic layer deposition (ALD) has been reported. The drawbacks are that the fluorine concentration in the gate dielectric is as low as 5.5E19/cm³, which 1) needs an another preceding fluorine treatment onto the semiconductor to realize a normally-off device; 2) is not high enough to conquer the positive charge in Al₂O₃ gate dielectric so that leads to a large hysteresis in capacitance-voltage (C-V) measurement (0.5V) and a large threshold hysteresis. Besides, the maximum threshold voltage among these devices is only 2.6V, while in some practical applications a threshold voltage as high as 3.0V is required. The maximum drain current is limited to below 800 mA/mm.

The fluorine treatment technique has been demonstrated to realize normally-off operation of nitride based HEMT (high electron mobility transistor) by placing the negatively charged fluorine atoms near the barrier/channel interface to lift up the potential well caused by polarization charge. In order to achieve high threshold voltage, high dosage and/or high energy fluorine treatment is required, which leads to a carrier screening of 2DEG (2-dimensional electron gas) and consequently reduces the drain current. Furthermore, the thermal diffusion of fluorine is a crucial concern of device reliability.

An innovative semiconductor device and a method of fabricating the same capable of disposing high-density fluorine near anode (gate) surface to enhance threshold voltage, reduce carrier screening to enhance drain current, and capable of enhancing the thermal stability of fluorine are desired.

### SUMMARY OF THE INVENTION

It is one object of the present invention to provide an improved nitride semiconductor device including a fluorinated anode structure which enhances fluorine concentration in the nitride semiconductor device and controls the depth of the fluorine in the device (the region where the fluorine is disposed as far away as possible) to improve the thermal and electrical stability of the device.

It is another object of the present invention to provide an improved high electron mobility transistor (HEMT) including an AlN anode dielectric layer (or gate dielectric layer) to avoid the problem of fluorinated Al₂O₃ anode dielectric layer in prior art, and to solve that the prior art required a trade-off between the thermal stability and threshold hysteresis, so as to solve the prior art shortcomings and drawbacks.

According to one embodiment, the fluorinated anode structure is compatible with an electron device including triode/diode. The threshold/forward voltage of the triode/anode can be modified by the fluorinated anode structure.

According to one embodiment, the present invention provides a high electron mobility transistor, including: a substrate; a channel layer disposed on the substrate; a nitride semiconductor layer disposed on the channel layer; a fluorinated anode structure disposed on the nitride semiconductor layer. The fluorinated anode structure includes an AlN anode dielectric layer on the nitride semiconductor layer, a fluorinated region in the AlN anode dielectric layer, and an anode metal layer disposed on the AlN anode dielectric layer; and a cathode structure disposed on the nitride semiconductor layer and in proximity to the fluorinated anode structure.

According to one embodiment, the AlN anode dielectric layer may include atomic bonding of AlFₓ and NFₓ. According to one embodiment, the AlN anode dielectric layer has a thickness ranging between 0.5 nm and 50 nm. According to one embodiment, the AlN anode dielectric layer has a fluorine concentration that is greater than or equal to 1E21 atoms/cm³. According to one embodiment, the fluorinated region extends into the nitride semiconductor layer and the fluorinated region is situated directly under the anode metal layer.

According to one embodiment, the anode metal layer may include TiN, TiN/Cu, Ti/TaN, Ta/TaN, TiN/Ti/Al/Ti/TiN, Ti, W, TiW, or a combination thereof.

According to one embodiment, the nitride semiconductor layer may include a barrier layer on the channel layer, and a spacer layer between the barrier layer and the channel layer. According to one embodiment, the channel layer may include GaN, AlGaN, AlInN, InGaN, AlGaInN, or a combination thereof. The barrier layer may include AlGaN, AlInN, AlInGaN, AlN, or a combination thereof. The spacer layer may include AlN.

According to one embodiment, the cathode structure includes a source electrode and a drain electrode disposed on the nitride semiconductor layer.

According to one embodiment, the high electron mobility transistor further includes a dielectric protection layer disposed between the anode metal layer and the AlN anode dielectric layer. The dielectric protection layer covers the source electrode and the drain electrode.

According to one embodiment, the high electron mobility transistor further includes an AlN interlayer in the barrier layer to enhance the fluorine concentration in the fluorinated anode structure.

According to one embodiment, the fluorinated anode structure further includes a recess region recessed into the nitride semiconductor layer. The anode metal layer fills into the recess region.

According to one embodiment, the high electron mobility transistor further includes a cap layer between the nitride semiconductor layer and the AlN anode dielectric layer. The cap layer may include GaN, AlGaN, AlInN, InGaN, AlGaInN, SiN, or a combination thereof.

In some embodiments, at least one recess region may be formed before, during, or after the fluorine treatment in order to block the fluorine as much as possible in the fluorinated anode structure and to enhance its stability.

In different embodiments, the recess region may have a depth reaching to the AlN anode dielectric layer, cap layer, barrier layer, spacer layer, or channel layer.

According to another embodiment, the present invention provides a high electron mobility transistor, including: a substrate; a channel layer disposed on the substrate; a nitride semiconductor layer disposed on the channel layer. The nitride semiconductor layer includes a spacer layer, such as AlN, and a barrier layer, such as AlGaN, AlInN, AlGaInN, AlN or a combination thereof. The high electron mobility transistor further includes a fluorinated anode structure disposed on the nitride semiconductor layer. The fluorinated anode structure includes an AlN anode dielectric layer on the nitride semiconductor layer, a cap layer, such as GaN or SiN cap layer, on the AlN anode dielectric layer, a fluorinated region in the AlN anode dielectric layer and the cap layer, and an anode metal layer disposed on the cap layer. The high electron mobility transistor further includes a cathode structure disposed on the nitride semiconductor layer and in proximity to the fluorinated anode structure.

According to another embodiment, the present invention provides a nitride semiconductor device, including: a substrate; a nitride semiconductor layer disposed on the substrate; an AlN anode dielectric layer disposed on the nitride semiconductor layer;

an anode metal layer disposed on the AlN anode dielectric layer; and a fluorinated region disposed in the AlN anode dielectric layer and extending into the nitride semiconductor layer. According to another embodiment, the AlN anode dielectric layer includes atomic bonding of AlFₓ and NFₓ. According to another embodiment, the AlN anode dielectric layer has a thickness ranging between 0.5 nm and 50 nm. According to another embodiment, the AlN anode dielectric layer has a fluorine concentration that is greater than or equal to 1E21 atoms/cm³.

In this disclosure, the fluorine treatment is applied to an AlN anode dielectric layer. Then an anode metal, preferably a TiN anode metal is disposed on the anode dielectric layer, to implement a fluorinated anode structure in an electron device. In some embodiments of the related method for implementing nitride high electron mobility transistor (HEMT)/Schottky Barrier Diodes (SBD) device, the fluorinated anode structure has the following advantages:

(1) Reduce the penetration depth of fluorine flux to protect the barrier/channel interface for enhancing the maximum drain current.
(2) Enhance the thermal stability of fluorine via the compound formation of NFx and enhance the incorporation concentration of fluorine via the compound formation of AlFx.
(3) A TiN gate metal (anode metal) is used to further suppress the out-diffusion of fluorine.
(4) Further exert the performance of nitride HEMT/SBD device with an AlInN, AlInGaN and AlN barrier layer that has much larger amount of polarization charge than AlGaN barrier layer. However, the nitride HEMT/SBD device with AlInN, AlInGaN and AlN barrier layer has extremely high polarization charge, making the critical voltage difficult to be higher than 1V. By disposing the fluorinated anode structure, the critical voltage can be made higher than 2V and protect the channel.
(5) Suppress current collapse, threshold hysteresis, and threshold thermal instability with AlN anode dielectric layer, without subjecting to the unable pinch-off issue. The electrical transconductance can be improved due to the suppression of current dispersion.
(6) Implement the reduced surface field (RESURF) structure by varying fluorine flux energy and dosage, over the gate region and/or the access region, to enhance the breakdown voltage and reduce the leakage current.
(7) The fluorinated anode structure and the anti-polarization layer act as mutually auxiliary technology to strengthen the RESURF structure for compensating the hugely positive polarization charge introduced by AlN layer.
(8) The fluorinated anode dielectric layer can further reduce the positively surface polarization charge to support larger voltage at off-state of the device, leading to an enhancement of breakdown voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram of a nitride semiconductor device according to an embodiment of the present invention.

FIG. 2A to FIG. 2L are schematic, cross-sectional diagrams showing an exemplary method of fabricating a nitride semiconductor device with a fluorinated anode structure.

FIG. 3 is a schematic, cross-sectional diagram of a nitride semiconductor device according to another embodiment of the present invention.

FIG. 3A to FIG. 3M are schematic, cross-sectional diagrams showing an exemplary method of fabricating a nitride semiconductor device with a fluorinated anode structure.

FIG. 4A to 4D are schematic, cross-sectional diagrams of a nitride semiconductor device with a reduced surface field (RESURF) region according to other embodiments of the present invention.

FIG. 5A to 5B are schematic, cross-sectional diagrams of a nitride semiconductor device with a recess region according to other embodiments of the present invention.

FIG. 6A to 6B are schematic, cross-sectional diagrams of a nitride semiconductor device with an AlN interlayer according to other embodiments of the present invention.

FIG. 7A to 7B are schematic, cross-sectional diagrams of a nitride semiconductor device with a recess region and an AlN interlayer according to other embodiments of the present invention.

FIG. 8A to 8D illustrate various nitride semiconductor devices as Schottky barrier diodes, respectively.

FIG. 9 illustrates a high electron mobility transistor, wherein a cap layer is formed on the AlN anode dielectric layer.

### DETAILED DESCRIPTION

The present invention will be readily understood by the following description and the numerous specific details provided. However, for those skilled in the art, the present invention may be practiced without these specific details. Furthermore, for simplicity, certain component configurations or process steps well known in the art are not described in detail herein, as these should be well known to those skilled in the art.

Likewise, the drawings of the embodiments are schematic diagrams which are magnified for clarity of presentation and are not drawn to actual proportions. Certain features, such as common or similar, are disclosed in the various embodiments disclosed and described herein, and similar features are denoted by like reference numerals for convenience of illustration and description.

The present invention provides an improved nitride semiconductor device including a novel fluorinated anode structure to avoid the problem of fluorinated Al₂O₃ anode dielectric layer in prior art, and to solve that the prior art required a trade-off between the thermal stability and threshold hysteresis.

In various embodiments, the fluorinated anode structure may be used, for example in triode, diodes, Schottky Barrier Diodes (SBD), high electron mobility transistors (HEMT), normally-off GaN MOS channel HEMT (MOSC-HEMT) and other nitride semiconductor device architectures to improve the stability and the operational reliability of the critical voltage or positive voltage.

Any electron device having the fluorinated anode structure may be fabricated using the method disclosed in the present invention, for example the electron device may be Schottky diode, tunneling diode, resonant tunneling diode, transistor, FET, MOSFET, CMOS, TFT, HEMT, LED, laser, or detector.

Furthermore, for fabricating HEMTs, the device operation mode may be normally-off or normally-on, used in a power converter, radio frequency (RF), or millimeter wave (MMW) applications.

FIG. 1 is a schematic, cross-sectional diagram of a nitride semiconductor device according to an embodiment of the present invention. As shown in FIG. 1, a nitride compound semiconductor device 1, such as a high electron mobility transistor (HEMT) or a gallium nitride (GaN) high electron mobility transistor, includes a substrate 100 including a silicon substrate, silicon carbide (SiC) substrate, sapphire substrate, gallium nitride (GaN) substrate, or aluminum nitride (AlN) substrate. A buffer layer 101 is formed on the substrate 100. For example, the buffer layer 101 may comprises GaN, AlGaN, AlInN, AlGaInN or AlN, but is not limited thereto.

According to an embodiment, an anti-polarization layer (APL) 102 is formed on the buffer layer 101. The APL 102 may include AlGaN, AlInN, AlGaInN, AlN, or a combination thereof. A channel layer 103 is formed on the APL 102. The channel layer 103 may include GaN, AlGaN, AlInN, InGaN, AlGaInN, or a combination thereof.

According to an embodiment, a nitride semiconductor layer 110 is formed on the channel layer 103. According to an embodiment, for example, the nitride semiconductor layer 110 includes a barrier layer 105 on the channel layer 103, and a spacer layer 104 between the barrier layer 105 and the channel layer 103. The barrier layer 105 may include AlGaN, AlInN, AlGaInN, AlN or a combination thereof. For example, the spacer layer 104 may include AlN.

According to an embodiment, the barrier layer 105 is preferably AlGaN, which can retain 2-dimensional electron gas (2DEG) in the nitride HEMT/SBD devices. In order to further increase the 2DEG density and mobility, an AlInN, an AlInGaN, or an AlN barrier layer may be introduced due to their relatively large polarization charge and energy band gap. However, this leads to a difficulty in realizing a normally-off device. Even when these barrier layers are used to realize the normally-on device, the unable pinch-off issue and huge hysteresis become detrimental to the device performance and stability.

By disposing the fluorinated anode structure on the nitride HEMT with AlGaN, AlInN, AlInGaN, or AlN barrier layer, the energy and dosage of fluorine plasma can be increased to enhance surface potential and density of negative charge, for effectively modify threshold voltage without degrading the drain current.

In some embodiments, the nitride compound semiconductor device 1 may be a Ga-polarity GaN HEMT and the barrier layer 105 located on the channel layer 103 may be used to retain 2-dimensional electron gas (2DEG) formed in the channel layer 103 and/or between the channel layer 103 and the barrier layer 105. Since the polarization charge between the barrier layer 105 and the channel layer 103 is positive, a potential dip is formed at the interface, and the free carrier is affected by the distribution of the polarization field and converges at the potential dip, thereby forming the 2DEG.

By disposing the anti-polarization layer 102 having a thickness and/or polarization field comparable to those of the barrier layer 105 below the channel layer 103, the tilted potential below the channel layer 103 can be changed so that the channel layer 103 can provide more free carriers to reach the potential dip between the barrier layer 105 and the channel layer 103, reducing the polarization charge on the surface of the nitride HEMT, thereby reducing surface field and improving the current collapse.

According to an embodiment, a material of the anti-polarization layer 102 is the same as a material of the barrier layer 105. According to an embodiment, the anti-polarization layer 102 may strengthen the RESURF structure for further reducing current collapse and/or threshold hysteresis. In some embodiments, the anti-polarization layer 102 and the barrier layer 105 may include III-nitride material of the same atomic composition. The thickness of the anti-polarization layer 102 is substantially the same as the thickness of the barrier layer 105 with a tolerance of ±25% in consideration of the feasibility process of the variation control.

According to an embodiment, the nitride semiconductor layer 110 may include a cap layer 106, for example, GaN, AlGaN, AlInN, InGaN, AlGaInN, or a combination thereof. In other embodiments, the cap layer 106 may be omitted.

According to an embodiment, a fluorinated anode structure 200 is disposed on a top surface 110a of the nitride semiconductor layer 110. According to an embodiment, the fluorinated anode structure 200 includes an AlN anode dielectric layer 220 on the top surface 110a of the nitride semiconductor layer 110, a fluorinated region 280 disposed in the AlN anode dielectric layer 220, and an anode metal layer 250 disposed on the AlN anode dielectric layer 220.

According to an embodiment, the fluorinated region 280 may be formed by a fluorine treatment before forming the anode metal layer 250. For example, the fluorinated region 280 may be formed by surface plasma treatment, atomic layer deposition (ALD), chemical vapor deposition (CVD), or ion implantation. The above-mentioned methods may further include a recess etching before, during, or after the fluorine treatment. Moreover, the recess region may be the same as (completely overlapping), or different (not completely overlapping) from the fluorinated region 280. The fluorine treatment may share the same photolithographic process with the gate metal deposition.

According to an embodiment, the nitride compound semiconductor device 1 further includes a cathode structure 230. According to an embodiment, the cathode structure 230 includes a source electrode 231 and a drain electrode 232. The cathode structure 230 is disposed together with the anode metal layer 250 on the top surface 110a of the nitride semiconductor layer 110 in a first direction D1.

According to an embodiment, the cathode structure 230 is in proximity to the fluorinated anode structure 200 in the first direction D1. The source electrode 231 is indirect contact with the nitride semiconductor layer 110 through an opening 220a in the AlN anode dielectric layer 220. The drain electrode 232 is in direct contact with the nitride semiconductor layer 110 through an opening 220b in the AlN anode dielectric layer 220.

According to an embodiment, the source electrode 231 and the drain electrode 232 are kept at a predetermined distance from the anode metal layer 250 and are electrically isolated from each other through a dielectric protection layer 240. According to an embodiment, the dielectric protection layer 240 is disposed between the anode metal layer 250 and the AlN anode dielectric layer 220 and covers the source electrode 231, the drain electrode 232, and AlN anode dielectric layer 220 in the first direction D1.

According to an embodiment, the dielectric protection layer 240 is disposed on the AlN anode dielectric layer 220 and is indirect contact with the AlN anode dielectric layer 220. According to an embodiment, the dielectric protection layer 240 may include AlN, Al₂O₃, SiN, SiO₂, ZrO, HfO₂, La₂O₃, Lu₂O₃, LaLuO₃, C₄F₈, or a combination thereof, such as SiN. According to an embodiment, the dielectric protection layer 240 is not only used for being electrically isolation, but also protects the AlN anode dielectric layer 220 to prevent the AlN anode dielectric layer 220 from being oxidized.

In some embodiments, the dielectric protection layer 240 may be disposed below the AlN anode dielectric layer 220, depending on the device design considerations of the anode dielectric layer or gate dielectric layer.

According to an embodiment, the fluorinated region 280 extends into the nitride semiconductor layer 110 and is disposed directly below the anode metal layer 250. According to an embodiment, an overlap of AlN anode dielectric layer 220 and the fluorinated region 280 includes atomic bonding of AlFₓ (actually, the aluminum atoms can be bonded to more than one fluorine, and thus may be represented as AlFₓ, where x is between 1 and 3), and atomic bonding of NFₓ (actually, the nitrogen atom can be bonded to more than one fluorine, and thus may be represented as NFₓ, where x is between 1 and 3). According to an embodiment, the formation N-F atomic bonding may enhance the thermal stability of fluorine and the formation of Al—F atomic bonding may enhance the incorporation of fluorine in the AlN anode dielectric layer 220.

Due to the formation of these bonds, fluorine atoms can be retained in the AlN anode dielectric layer 220 as much as possible to increase the fluorine concentration in the AlN anode dielectric layer 220 while reducing the downward penetration depth of fluorine. In other words, the AlN anode dielectric layer 220 may be considered as a decelerator layer of fluorine flux or a fluorine trapping layer. In addition, according to an embodiment, the material of the dielectric protection layer 240 may be, such as, SiN, which is contributed to the above-mentioned decelerator layer of fluorine flux and reducing the downward penetration depth of fluorine.

According to an embodiment, optionally, an extended fluorinated region 282 that is contiguous with the fluorinated region 280 is further formed in the AlN anode dielectric layer 220 in the first direction D1. The extended fluorinated region 282 may be referred to as RESURF region.

According to an embodiment, the fluorine concentration in the channel layer 103 is less than or equal to 5E17 atoms/cm³.

According to an embodiment, the AlN anode dielectric layer 220 has a thickness ranging between 0.5 nm and 50 nm, but is not limited thereto. According to an embodiment, the AlN anode dielectric layer 220 has a fluorine concentration that is greater than or equal to 1E21 atoms/cm³. According to an embodiment, the greatest fluorine concentration in the fluorinated region 280 may be located in the AlN anode dielectric layer 220 and the fluorine concentration thereof is decreasing downward in a second direction D2 (i.e., the thickness direction of the nitride compound semiconductor device 1).

However, in some embodiments, it should be noted that the fluorine concentration is decreasing downward in a second direction D2 from the greatest fluorine concentration of the AlN anode dielectric layer 220 (i.e., in the direction toward the channel layer 103), the fluorine concentration may be suddenly increased in the nitride semiconductor layer 110, for example, the spacer layer 104, where the fluorine concentration depth profile exhibits a relatively high peak.

According to an embodiment, the anode metal layer 250 includes TiN, TiN/Cu, Ti/TaN, Ta/TaN, TiN/Ti/Al/Ti/TiN, Ti, W, TiW, or a combination thereof. For example, the anode metal layer 250 may be composed by TiN or a metal stack structure composed of TiN as a first layer (in direct contact with the AlN anode dielectric layer 220) The TiN can effectively suppress the out-diffusion of fluorine.

For example, in some embodiments, the anode metal layer 250 may be a stack structure including titanium nitride/titanium/aluminum/titanium/titanium nitride. The stack structure maintains a certain thickness while reducing the stress in the metal stack. In some further embodiments, after forming the titanium nitride or titanium nitride/titanium/aluminum/titanium/titanium nitride stack, then other metals may be stacked, or further process may be performed, for example, metallization, electrical connection of the elements and/or reducing anode resistance.

According to an embodiment, the nitride compound semiconductor device 1 further includes a dielectric passivation layer 260 covering the anode metal layer 250 and the dielectric protection layer 240. According to an embodiment, the dielectric passivation layer 260 includes AlN, Al₂O₃, SiN, SiO₂, ZrO, HfO₂, La₂O₃, Lu₂O₃, LaLuO₃, C₄F₈, or a combination thereof.

In the related prior arts, the Al₂O₃ layer has become a prevailing gate dielectric to suppress gate leakage current due to its large energy band gap. However, the parasitic positive charge in Al₂O₃ and at Al₂O₃/nitride interface causes threshold hysteresis. Moreover, the Al₂O₃ gate dielectric/passivation layer alone cannot suppress current collapse under high-temperature stress as AlN layer can do.

On the other hand, the thermal diffusion of fluorine in AlGaN barrier layer and Al₂O₃ dielectric layer could be a potential issue of device reliability, which calls for the need of a more robust dielectric being fluorine compatible. Fluorine tends to combine with aluminum due to its extremely large electronegativity, which is helpful for improving thermal stability and incorporation concentration of fluorine.

Theoretically, the stoichiometry of AlN (Al:N=1:1) favors the fluorine incorporation more than Al₂O₃ (Al:O=2:3), and therefore AlN is a much superior candidate of fluorinated gate dielectric. On the other hand, the NFₓ in fluorinated AlN layer is stable for keeping a high level of fluorine concentration in the dielectric layer. Fluorine in the Al₂O₃ replaces the oxygen atoms, while fluorine in AlN is bonded with aluminum and nitrogen at the same time, thus effectively enhance the fluorine content in the nitride compound layer, and enhance the overall bond strength and stability. In addition, the fluorine treatment on the Al₂O₃ surface will increase the leakage current, while the fluorine treatment on the AlN surface can suppress the leakage current. The AlN dielectric also can act as a decelerator of fluorine flux to reduce its penetration depth and/or to suppress its etching behavior for improving device performance. Consequently, by replacing Al₂O₃ with AlN as a fluorinated dielectric, the stability and concentration of fluorine can be significantly enhanced.

Apart from the electrical characteristics influenced by the un-optimized fluorine-plasma treatment in prior arts, the thermal stability is another critical issue of the device reliability. A MOSC-HEMT with improved thermal stability of threshold voltage has been reported, by removing part of the AlGaN barrier layer to reduce the surface polarization at the cost of degradation of drain current. On the other hand, the AlN gate dielectric/passivation layer has been demonstrated to suppress current collapse under high-temperature stress, due to its high density of polarization charge. However, the hugely and positively surface polarization charge caused by AlN surface layer results in an unable pinch-off issue even when the gate-source bias reaches −12V. Furthermore, the net positive polarization charge in the AlN/nitride interface results in the threshold hysteresis. Consequently, there is an undesired trade-off between threshold stability and current collapse when the electron device adopts AlN passivation/gate dielectric layer, which retards the advancing of industry in power electronics. Therefore, a novel anode structure and passivation particularly in nitride HEMT, and its fabrication method to further improve device performance, are well desired. Overall, the development of fluorinated AlN anode dielectric layer can improve the following two aspects: 1) when the device is made of Al₂O₃ as the anode dielectric layer and is subjected to fluorine treatment to achieve a normally-off device, the leakage current will increase and the concentration and stability of fluorine still be improved; 2) When the device (including normally-off and normally-on elements) with AlN as the anode dielectric layer to suppress the current collapse, the hugely positive polarization charge introduced by AlN layer leads to threshold hysteresis, resulting in normally-off element difficult to achieve and an unable pinch-off issue. Therefore, the present invention provides an innovative anode structure and passivation in nitride HEMT and the fabricating method thereof, which will break through the trade-off bottleneck in the development process of the technology and further improve the performance of the device, thereby making the development of the field to achieve a significant process and promoting a large number of devices of business opportunity. In general, a fluorinated AlN anode dielectric layer can enhance the critical voltage of the devices, suppress the leakage current and current collapse, improve the threshold hysteresis, and make the devices be normally shut down under operating conditions. In addition, the current capability of the devices can be greatly improved and the reliability of the devices can be improved.

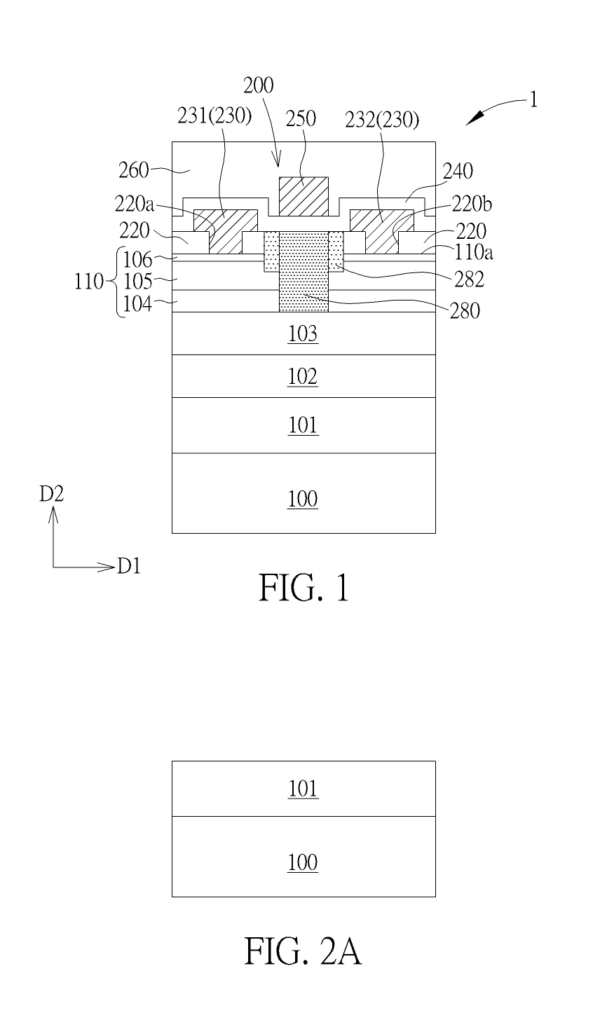

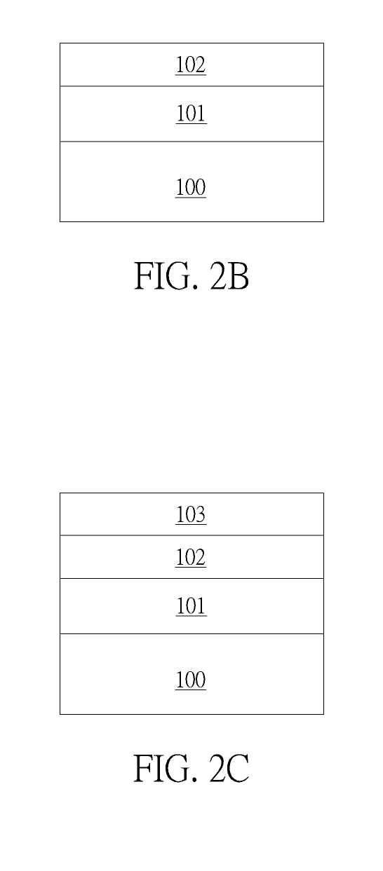

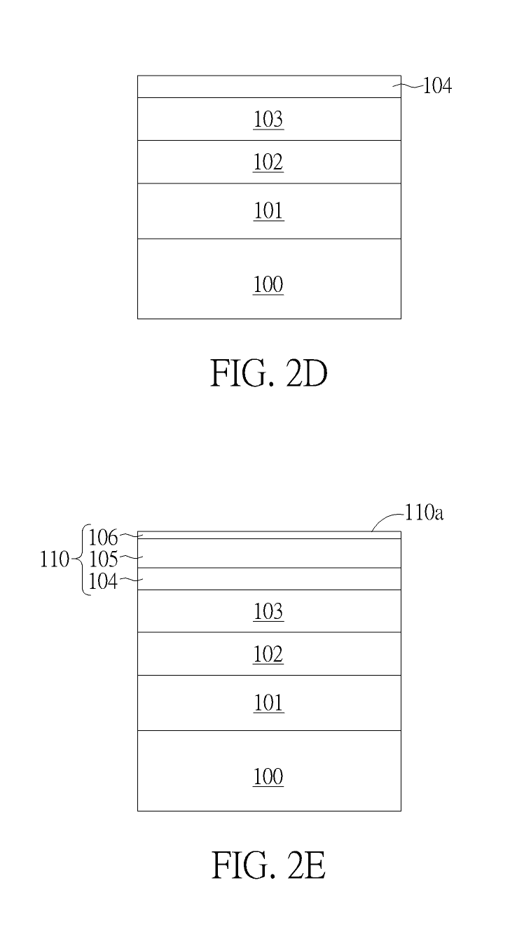

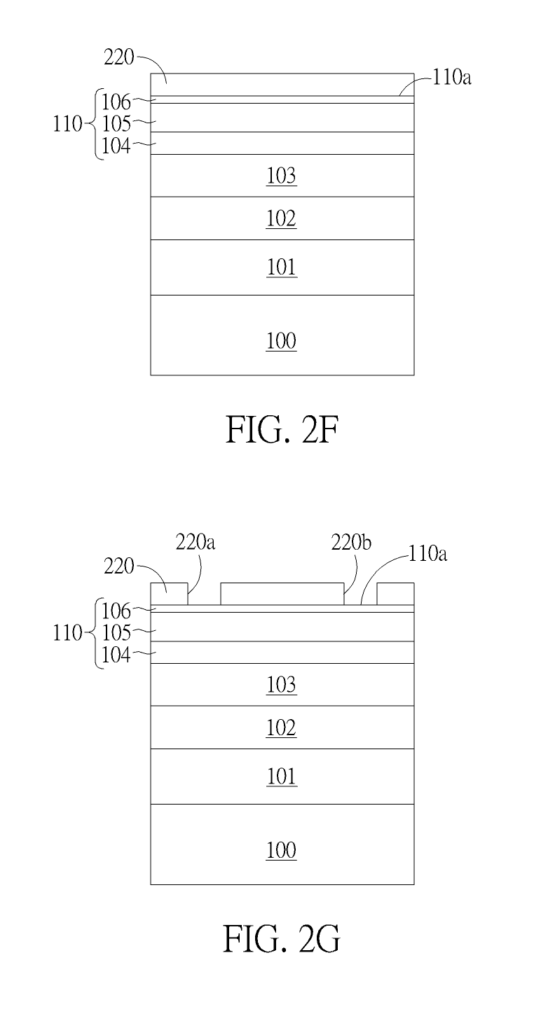

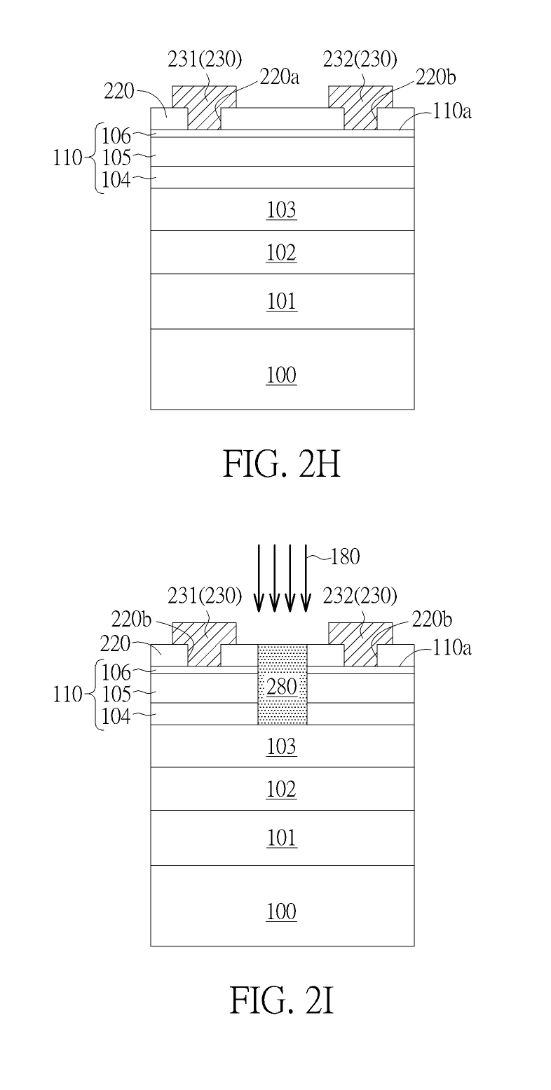

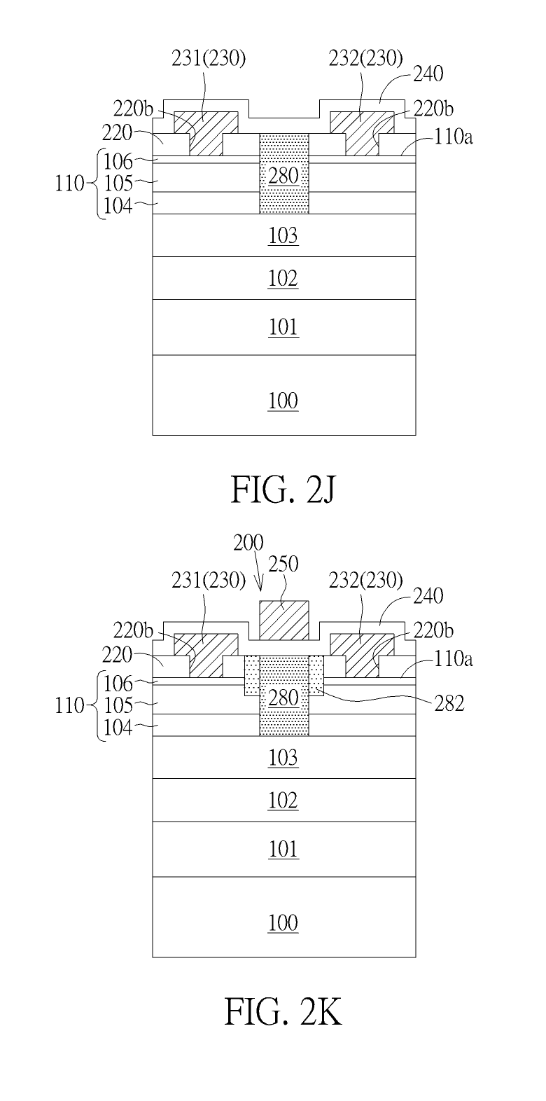

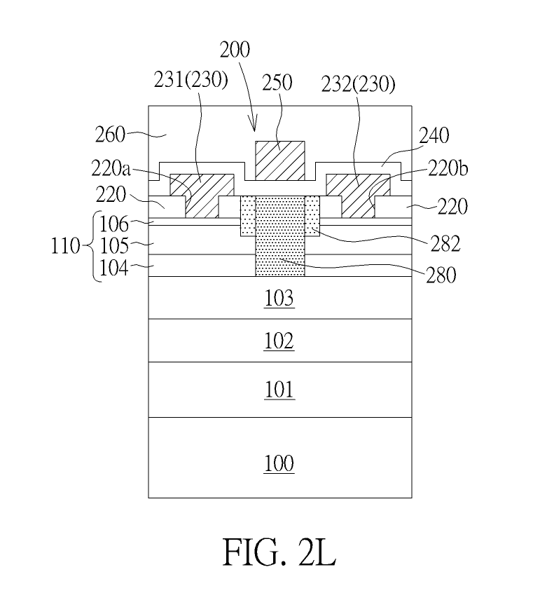

FIG. 2A to FIG. 2L are schematic, cross-sectional diagrams showing an exemplary method of fabricating a nitride semiconductor device with a fluorinated anode structure. The epitaxial method of III-nitride material may include, but not limited to, molecule beam epitaxy (MBE), metal-organic chemical vapor deposition (MOCVD), or hydride vapor phase deposition (HVPE).

As shown in FIG. 2A, a substrate 100 is first provided, such as a silicon substrate, a silicon carbide substrate, a sapphire substrate, a gallium nitride substrate, or an aluminum nitride substrate. Next, a buffer layer 101 is epitaxially grown on the substrate 100. The buffer layer 101 may be, for example, a III-V group compound semiconductor such as GaN, AlGaN, AlInN, AlGaInN or AlN.

As shown in FIG. 2B, an anti-polarization layer (APL) 102 is epitaxially grown on the buffer layer 101. The APL 102 may include AlGaN, AlInN, AlGaInN, AlN, or a combination thereof.

Next, as shown in FIG. 2C, a channel layer 103 is epitaxially grown on the APL 102. The channel layer 103 may include GaN, AlGaN, AlInN, InGaN, AlGaInN, or a combination thereof.

Next, as shown in FIG. 2D, a spacer layer 104 is epitaxially grown on the channel layer 103. The spacer layer 104 may include AlN.

Next, as shown in FIG. 2E, a barrier layer 105 is epitaxially grown on the spacer layer 104. The barrier layer 105 may include AlGaN, AlInN, AlGaInN, AlN or a combination thereof. According to an embodiment, the barrier layer 105 is preferably AlGaN, which can retain 2-dimensional electron gas (2DEG) formed in the channel layer 103 and/or between the channel layer 103 and the barrier layer 105.

By disposing the anti-polarization layer 102 having a thickness and/or polarization field comparable to those of the barrier layer 105 below the channel layer 103, the tilted potential below the channel layer 103 can be changed so that the channel layer 103 can provide more free carriers to reach the potential dip between the barrier layer 105 and the channel layer 103, reducing the polarization charge on the surface of the nitride HEMT, thereby reducing surface field and improving the current collapse. According to an embodiment, a material of the anti-polarization layer 102 is the same as a material of the barrier layer 105.

According to an embodiment, a material of the anti-polarization layer 102 is the same as a material of the barrier layer 105. According to an embodiment, the anti-polarization layer 102 may strengthen the RESURF structure for further reducing current collapse and/or threshold hysteresis. In some embodiments, the anti-polarization layer 102 and the barrier layer 105 may include III-nitride material of the same atomic composition. The thickness of the anti-polarization layer 102 is substantially the same as the thickness of the barrier layer 105 with a tolerance of ±25% in consideration of the feasibility process of the variation control.

Next, a cap layer 106 is epitaxially grown on the barrier layer 105. The cap layer 106 may include, for example, GaN, AlGaN, AlInN, InGaN, AlGaInN, or a combination thereof. In other embodiments, the cap layer 106 may be omitted. At this time, the nitride semiconductor layer 110 is completed on the channel layer 103.

Next, as shown in FIG. 2F, an AlN anode dielectric layer 220 is formed on the nitride semiconductor layer 110. The AlN anode dielectric layer 220 may be formed by utilizing a process, including, but not limited to, molecule beam epitaxy (MBE), metal-organic chemical vapor deposition (MOCVD), hydride vapor phase deposition (HVPE), atomic layer deposition (ALD), or plasma-enhanced ALD (PEALD). According to an embodiment, the AlN anode dielectric layer 220 has a thickness ranging between 0.5 nm and 50 nm, but is not limited thereto.

In some embodiments, if the AlN anode dielectric layer 220 is formed by ALD, the cap layer 106 is formed under the AlN anode dielectric layer 220 by MOCVD, as shown in FIG. 2E to 2F.

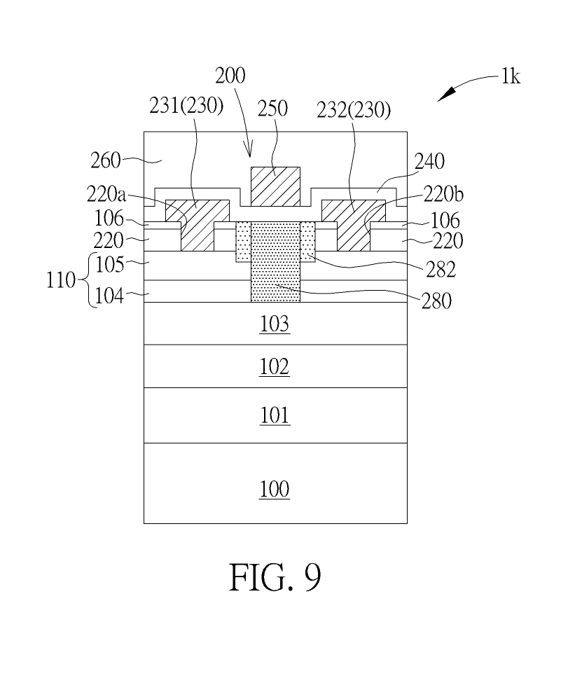

In some embodiments, if the AlN anode dielectric layer 220 is formed by MOCVD, the cap layer 106 is formed on the AlN anode dielectric layer 220. FIG. 9 illustrates a high electron mobility transistor 1k, wherein a cap layer 106 is formed on the AlN anode dielectric layer 220. The same layers, regions, or elements are still represented by the same numeral numbers. As shown in FIG. 9, the high electron mobility transistor 1k includes a substrate 100; a channel layer 103 disposed on the substrate 100; and a nitride semiconductor layer 110 disposed on the channel layer 103. The nitride semiconductor layer 110 includes a spacer layer 104, such as AlN, and a barrier layer 105, such as AlGaN, AlInN, AlGaInN, AlN or a combination thereof.

The high electron mobility transistor 1k further includes a fluorinated anode structure 200 disposed on the nitride semiconductor layer 110. The fluorinated anode structure 200 includes an AlN anode dielectric layer 220 on the nitride semiconductor layer 110, a cap layer 106, such as GaN or SiN cap layer, on the AlN anode dielectric layer 220, a fluorinated region 280 in the AlN anode dielectric layer 220 and the cap layer 106, and an anode metal layer 250 disposed on the cap layer 106. The high electron mobility transistor 1k further includes a cathode structure 230 disposed on the nitride semiconductor layer 110 and in proximity to the fluorinated anode structure 200.

Next, as shown in FIG. 2G, an opening 220a and an opening 220b are formed in the AlN anode dielectric layer 220 by a lithography and etching process, in which the opening 220a and the opening 220b respectively exposed a portion of a top surface 110a of the nitride semiconductor layer 110 predetermined contacting with the cathode electrode (take HEMT as an example, including source electrode and drain electrode).

Next, as shown in FIG. 2H, a source electrode 231 and a drain electrode 232 are formed respectively in the opening 220a and the opening 220b, for example, by an e-gun evaporator or sputtering. The source electrode 231 and the drain electrode 232 are partially extended onto the surface of the AlN anode dielectric layer 220, so that the source electrode 231 and the drain electrode 232 are respectively shown as a T-profile.

Next, as shown in FIG. 2I, a fluorine treatment is performed to form a fluorinated region 280 in the AlN anode dielectric layer 220. According to an embodiment, the fluorinated region 280 extends into the nitride semiconductor layer 110 and is disposed directly below the anode metal layer 250.

Depending upon the fluorine flux, energy and the processing time, the fluorine may penetrate into the barrier layer 105, the spacer layer 104, the channel layer 103, or, in other embodiments, deeper into the buffer layer 101. Consequently, the fluorinated region 280 may include at least a portion of AlN layer 220, barrier layer 105, spacer layer 104, channel layer 103, but is not limited thereto.

According to an embodiment, an overlapping region between the AlN anode dielectric layer 220 and the fluorinated region 280 includes N—F atomic bonding and Al—F atomic bonding. According to an embodiment, the formation N—F atomic bonding may enhance the thermal stability of fluorine and the formation of Al—F atomic bonding may enhance the incorporation of fluorine in the AlN anode dielectric layer 220.

According to an embodiment, the AlN anode dielectric layer 220 has a fluorine concentration that is greater than or equal to 1E21 atoms/cm².

For example, the fluorine treatment for forming the fluorinated region may be performed in one of the following tools: inductor-coupled plasma (ICP), reactive ion etching (RIE), RIE-ICP, ICP-RIE, capacitor-coupled etch (CCP), transformer-coupled etching (TCP), electron cyclotron resonance (ECR), atomic layer deposition (ALD), chemical vapor deposition (CVD), plasma-enhanced CVD (PECVD), low-pressure CVD (LPCVD), physical vapor deposition (PVD), ion implantor.

It should be noted that, the fluorine treatment may be performed at any stage after completion of the AlN anode dielectric layer 220 in FIGS. 2F to 2H in other embodiments.

Next, as shown in FIG. 2J, a dielectric protection layer 240 is conformally formed on the AlN anode dielectric layer 220, the source electrode 231 and the drain electrode 232. The dielectric protection layer 240 covers the source electrode 231, the drain electrode 232, and AlN anode dielectric layer 220 in the first direction D1. According to an embodiment, the dielectric protection layer 240 is disposed on the AlN anode dielectric layer 220 and is in direct with the AlN anode dielectric layer 220.

According to an embodiment, the dielectric protection layer 240 may include AlN, Al₂O₃, SiN, SiO₂, ZrO, HfO₂, La₂O₃, Lu₂O₃, LaLuO₃, C₄F₈, or a combination thereof, such as SiN. According to an embodiment, the dielectric protection layer 240 is not only used for electrically isolation, but also protects the AlN anode dielectric layer 220 to prevent the AlN anode dielectric layer 220 from being oxidized. Furthermore, the dielectric protection layer 240 may be fluorinated.

According to an embodiment, the dielectric protection layer 240 may be formed by atomic layer deposition (ALD), plasma-enhanced ALD (PEALD), chemical vapor deposition (CVD), plasma-enhanced CVD (PECVD), or low-pressure CVD (LPCVD).

Next, as shown in FIG. 2K, an anode metal layer 250 is formed on the dielectric protection layer 240 and is disposed directly above the fluorinated region 280. Before forming the anode metal layer 250, a fluorine treatment may be performed to form an extended fluorinated region 282 that is contiguous with the fluorinated region 280 in the AlN anode dielectric layer 220. The fluorine concentration in the extended fluorinated region 282 may be the same as or different from the fluorine concentration in the fluorinated region 280. The extended fluorinated region 282 may be distributed to the cap layer 106 and a portion of the barrier layer 105 in the second direction D2.

According to an embodiment, the anode metal layer 250 may include TiN, TiN/Cu, Ti/TaN, Ta/TaN, TiN/Ti/Al/Ti/TiN, Ti, W, TiW, or a combination thereof. For example, the anode metal layer 250 may be composed by TiN or a metal stack structure composed of TiN as a first layer (in direct contact with the AlN anode dielectric layer 220). The TiN can effectively suppress the out-diffusion of fluorine.

For example, in some embodiments, the anode metal layer 250 may be a stack structure including titanium nitride/titanium/aluminum/titanium/titanium nitride. The stack structure maintains a certain thickness while reducing the stress in the metal stack. In some further embodiments, after forming the titanium nitride or titanium nitride/titanium/aluminum/titanium/titanium nitride stack, then other metals may be stacked, or further process may be performed, for example, metallization, electrical connection of the elements and/or reducing anode resistance. At this time, the production of the fluorinated anode structure 200 is completed.

Next, as shown in FIG. 2L, a dielectric passivation layer 260 is formed to cover the anode metal layer 250 and the dielectric protection layer 240, for example, by chemical vapor deposition (CVD), plasma-enhanced CVD (PECVD) or low-pressure CVD (LPCVD). According to an embodiment, the dielectric passivation layer 260 may include AlN, Al₂O₃, SiN, SiO₂, ZrO, HfO₂, La₂O₃, Lu₂O₃, LaLuO₃, C₄F₈, or a combination thereof.

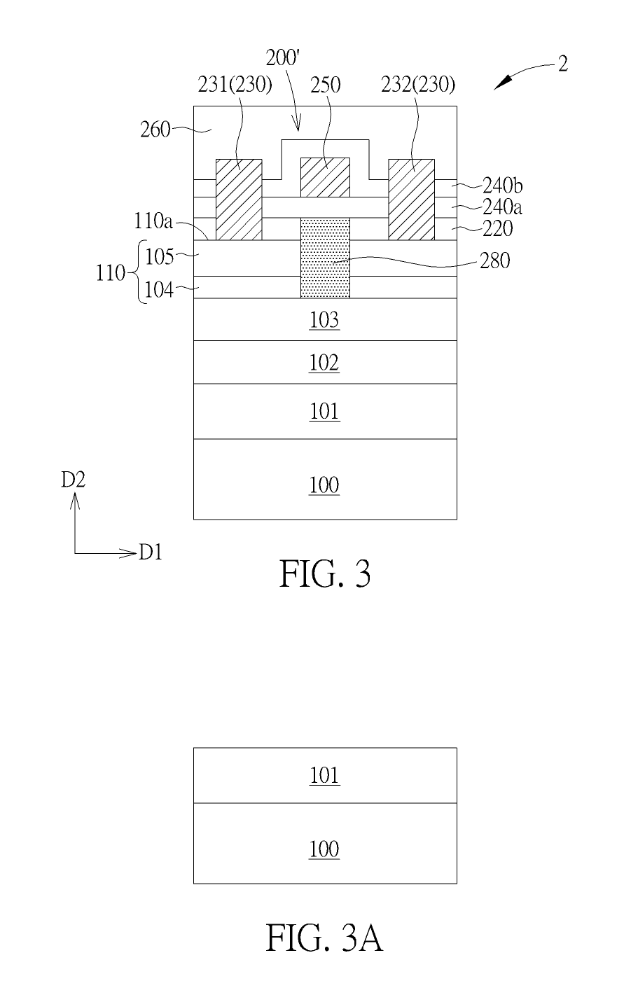

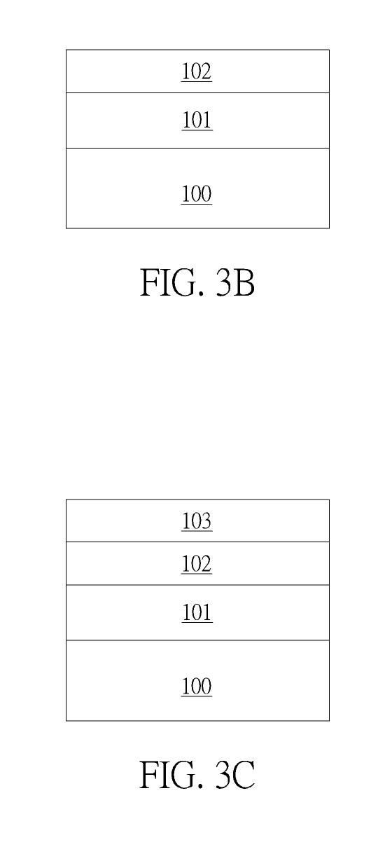

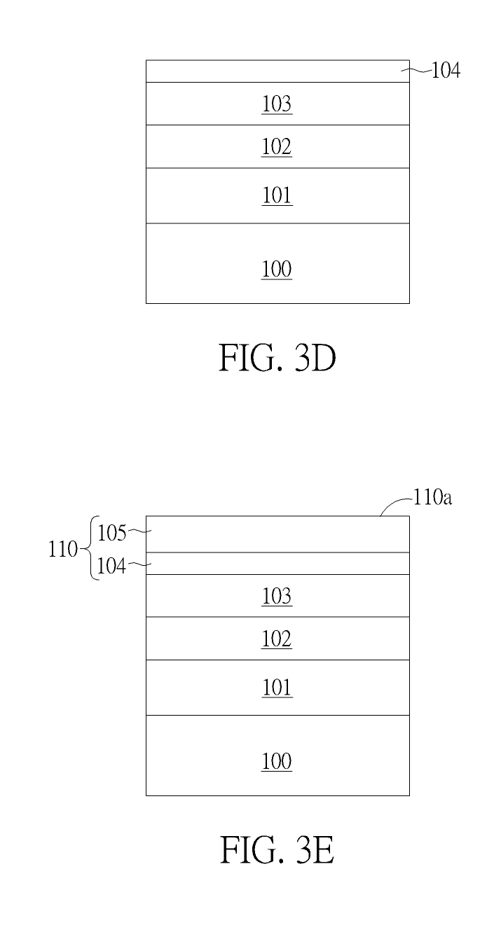

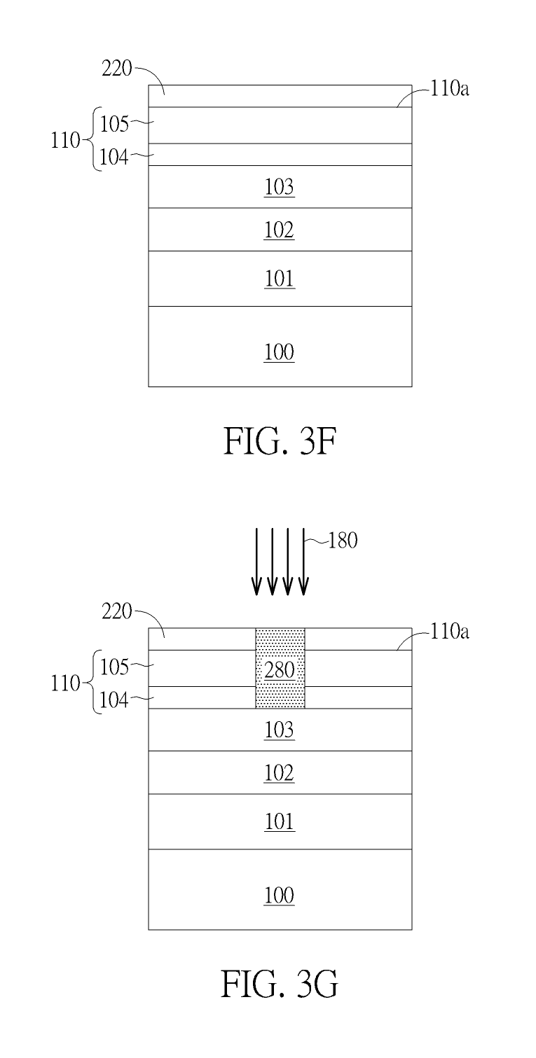

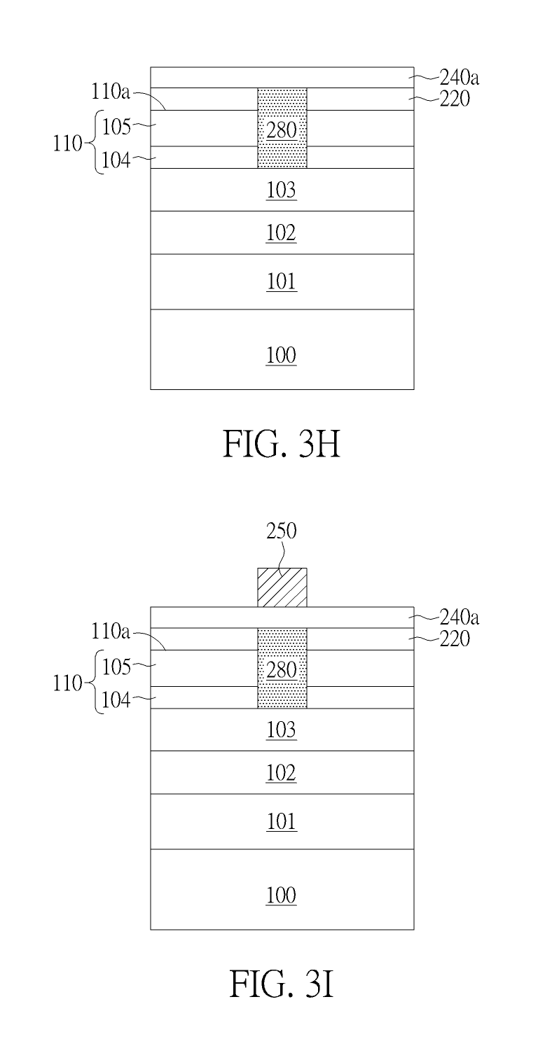

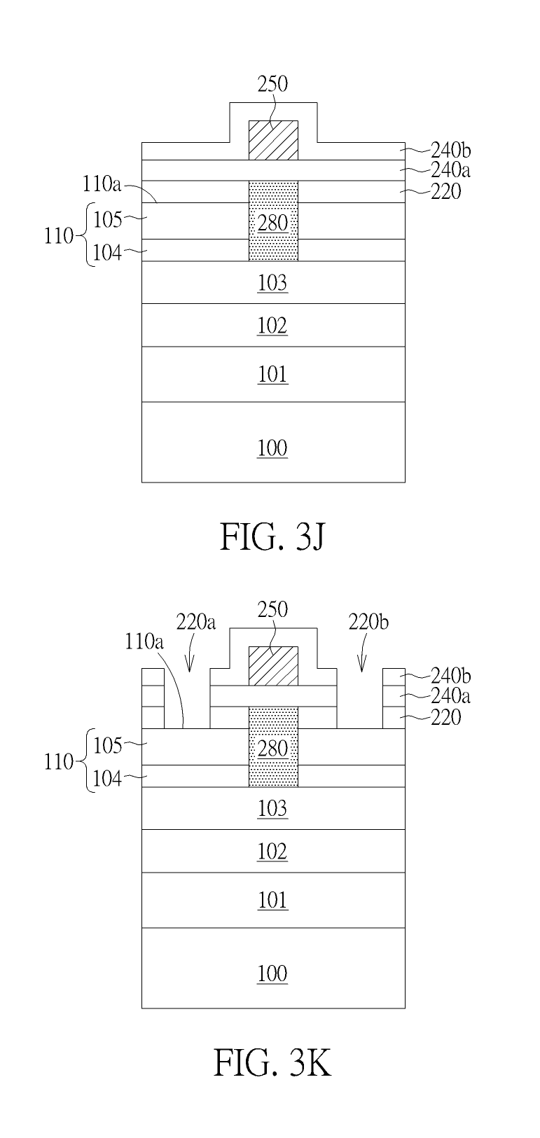

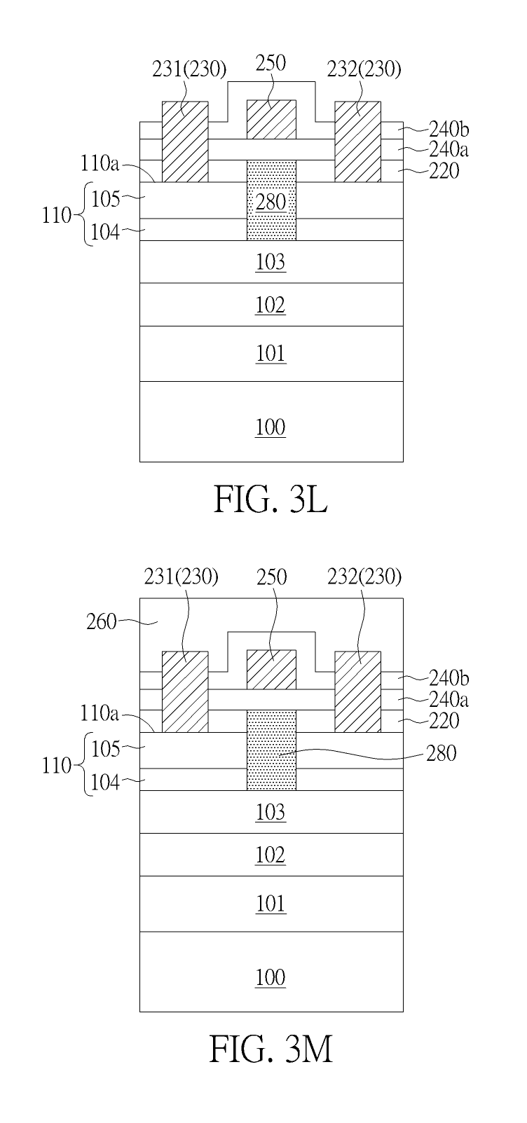

FIG. 3 is a schematic, cross-sectional diagram of a nitride semiconductor device according to another embodiment of the present invention, wherein the same layers, regions, or elements are still represented by the same numeral numbers.

As shown in FIG. 3, a nitride compound semiconductor device 2 such as a high electron mobility transistor (HEMT) or a gallium nitride (GaN) high electron mobility transistor, includes a substrate 100 including a silicon substrate, silicon carbide (SiC) substrate, sapphire substrate, gallium nitride (GaN) substrate, or aluminum nitride (AlN) substrate. The substrate 100 is formed with a buffer layer 101, for example, GaN, AlGaN, AlInN, AlGaInN or AlN., but is not limited thereto.

According to an embodiment, an anti-polarization layer (APL) 102 is formed on the buffer layer 101 The APL 102 may include AlGaN, AlInN, AlGaInN, AlN, or a combination thereof. A channel layer 103 is formed on the APL 102 The channel layer 103 may include GaN, AlGaN, AlInN, InGaN, AlGaInN, or a combination thereof. A nitride semiconductor layer 110 is formed on the channel layer 103. According to an embodiment, for example, the nitride semiconductor layer 110 may include a barrier layer 105 and a spacer layer 104. The barrier layer 105 may include AlGaN, AlInN, AlGaInN, AlN or a combination thereof. For example, the spacer layer 104 may include AlN. The nitride semiconductor layer 110 may include a cap layer 106 (not shown).

According to an embodiment, a fluorinated anode structure 200′ is disposed on a top surface 110a of the nitride semiconductor layer 110. According to an embodiment, the fluorinated anode structure 200′ includes an AlN anode dielectric layer 220 on the top surface 110a of the nitride semiconductor layer 110, a fluorinated region 280 disposed in the AlN anode dielectric layer 220, and an anode metal layer 250 disposed on the AlN anode dielectric layer 220.

According to an embodiment, the fluorinated region 280 may be formed by a fluorine treatment before forming the anode metal layer 250. For example, it may be formed by surface plasma treatment, atomic layer deposition (ALD), chemical vapor deposition (CVD), or ion implantation.

As shown in FIG. 3, the nitride compound semiconductor device 2 further includes a first dielectric protection layer disposed between the AlN anode dielectric layer 220 and the anode metal layer 250. For example, the first dielectric protection layer 240a may be a silicon nitride layer, but is not limited thereto. The nitride compound semiconductor device 2 further includes a second dielectric protection layer 240b disposed on the anode metal layer 250. The second dielectric protection layer 240b is conformally covered the anode metal layer 250 and the first dielectric protection layer 240a. For example, the second dielectric protection layer 240b may be a silicon nitride layer, but is not limited thereto.

According to an embodiment, the nitride compound semiconductor device 2 further includes a cathode structure 230. According to an embodiment, the cathode structure 230 includes a source electrode 231 and a drain electrode 232. The cathode structure 230 is disposed together with the anode metal layer 250 on the top surface 110a of the nitride semiconductor layer 110 in a first direction D1.

According to an embodiment, the cathode structure 230 is in proximity to the fluorinated anode structure 200′ in the first direction D1. The source electrode 231 is extended through the second dielectric protection layer 240b, the first dielectric protection layer 240a and the AlN anode dielectric layer 220 and is in direct contact with the nitride semiconductor layer 110. The drain electrode 232 is extended through the second dielectric protection layer 240b, the first dielectric protection layer 240a and the AlN anode dielectric layer 220 and is in direct contact with the nitride semiconductor layer 110.

According to an embodiment, the source electrode 231 and the drain electrode 232 are kept at a predetermined distance from the anode metal layer 250 and are electrically isolated from each other through the second dielectric protection layer 240b.

As can be seen from comparison between FIG. 1 and FIG. 3, the nitride compound semiconductor device 1 shown in FIG. 1 differs from the nitride compound semiconductor device 2 shown in FIG. 3 in that the nitride compound semiconductor device 1 shown in FIG. 1 is completed by a gate-last process, while the nitride compound semiconductor device 2 shown in FIG. 3 is completed by a gate-first process. Therefore, a second dielectric protection layer 240b is formed on the anode metal layer 250 of the nitride compound semiconductor device 2 shown in FIG. 3.

According to an embodiment, the first dielectric protection layer 240a and the second dielectric protection layer 240b are disposed on the AlN anode dielectric layer 220. The first dielectric protection layer 240a is in direct contact with the AlN anode dielectric layer 220. According to an embodiment, the first dielectric protection layer 240a and the second dielectric protection layer 240b include AlN, Al₂O₃, SiN, SiO₂, ZrO, HfO₂, La₂O₃, Lu₂O₃, LaLuO₃, C₄F₈, or a combination thereof, such as SiN. According to an embodiment, the first dielectric protection layer 240a is not only used for being electrically isolation, but also protects the AlN anode dielectric layer 220 to prevent the AlN anode dielectric layer 220 from being oxidized.

According to an embodiment, the fluorinated region 280 extends into the nitride semiconductor layer 110 and is disposed directly below the anode metal layer 250. According to an embodiment, an overlapping region between the AlN anode dielectric layer 220 and the fluorinated region 280 may include N—F atomic bonding and Al—F atomic bonding. According to an embodiment, the formation an N—F atomic bonding may enhance the thermal stability of fluorine and the formation of Al—F atomic bonding may enhance the incorporation of fluorine in the AlN anode dielectric layer 220.

According to an embodiment, the fluorine concentration in the channel layer 103 is less than or equal to 5E17 atoms/cm³.

According to an embodiment, the AlN anode dielectric layer 220 has a thickness ranging between 0.5 nm and 50 nm, but is not limited thereto. According to an embodiment, the AlN anode dielectric layer 220 has a fluorine concentration that is greater than or equal to 1E21 atoms/cm³. According to an embodiment, the greatest fluorine concentration in the fluorinated region 280 is located in the AlN anode dielectric layer 220 and the fluorine concentration thereof is decreasing downward in a second direction D2 (i.e., the thickness direction of the nitride compound semiconductor device 2).

However, in some embodiments, it should be noted that the fluorine concentration is decreasing downward in a second direction D2 from the greatest fluorine concentration of the AlN anode dielectric layer 220 (i.e., in the direction toward the channel layer 103), the fluorine concentration may be suddenly increased in the nitride semiconductor layer 110, for example, the spacer layer 104, where the fluorine concentration depth profile exhibits a relatively high peak.

According to an embodiment, the anode metal layer 250 may include TiN, TiN/Cu, Ti/TaN, Ta/TaN, TiN/Ti/Al/Ti/TiN, Ti, W, TiW, or a combination thereof. For example, the anode metal layer 250 may be composed by TiN or a metal stack structure composed of TiN as a first layer (in direct contact with the first dielectric protection layer 240a) The TiN can effectively suppress the out-diffusion of fluorine.

For example, in some embodiments, the anode metal layer 250 may be a stack structure including titanium nitride/titanium/aluminum/titanium/titanium nitride. The stack structure maintains a certain thickness while reducing the stress in the metal stack. In some further embodiments, after forming the titanium nitride or titanium nitride/titanium/aluminum/titanium/titanium nitride stack, then other metals may be stacked, or further process may be performed, for example, metallization, electrical connection of the elements and/or reducing anode resistance.

According to an embodiment, the nitride compound semiconductor device 2 further includes a dielectric passivation layer 260 covering the anode metal layer 250 and the second dielectric protection layer 240b. According to an embodiment, the dielectric passivation layer 260 may include AlN, Al₂O₃, SiN, SiO₂, ZrO, HfO₂, La₂O₃, Lu₂O₃, LaLuO₃, C₄F₈, or a combination thereof.

FIG. 3A to FIG. 3M are schematic, cross-sectional diagrams showing an exemplary method of fabricating a nitride semiconductor device with a fluorinated anode structure. Regarding an epitaxial method of III-nitride material may include molecule beam epitaxy (MBE), metal-organic chemical vapor deposition (MOCVD), and hydride vapor phase deposition (HVPE).

As shown in FIG. 3A, a substrate 100 is first provided, such as a silicon substrate, a silicon carbide substrate, a sapphire substrate, a gallium nitride substrate, or an aluminum nitride substrate. Next, a buffer layer 101 is epitaxially grown on the substrate 100. The buffer layer 101 may be, for example, a III-V group compound semiconductor such as GaN, AlGaN, AlInN, AlGaInN or AlN.

As shown in FIG. 3B, an anti-polarization layer (APL) 102 is epitaxially grown on the buffer layer 101 The APL 102 may include AlGaN, AlInN, AlGaInN, AlN, or a combination thereof.

Next, as shown in FIG. 3C, a channel layer 103 is epitaxially grown on the APL 102 The channel layer 103 may include GaN, AlGaN, AlInN, InGaN, AlGaInN, or a combination thereof.

Next, as shown in FIG. 3D, a spacer layer 104 is epitaxially grown on the channel layer 103. The spacer layer 104 may include AlN.

Next, as shown in FIG. 3E, a barrier layer 105 is epitaxially grown on the spacer layer 104. The barrier layer 105 may include AlGaN, AlInN, AlGaInN, AlN or a combination thereof. According to an embodiment, the barrier layer 105 is preferably AlGaN, which can retain 2-dimensional electron gas (2DEG) formed in the channel layer 103 and/or between the channel layer 103 and the barrier layer 105.

By disposing the anti-polarization layer 102 having a thickness and/or polarization field comparable to those of the barrier layer 105 below the channel layer 103, the tilted potential below the channel layer 103 can be changed so that the channel layer 103 can provide more free carriers to reach the potential dip between the barrier layer 105 and the channel layer 103, reducing the polarization charge on the surface of the nitride HEMT, thereby reducing surface field and improving the current collapse. According to an embodiment, a material of the anti-polarization layer 102 is the same as a material of the barrier layer 105.

According to an embodiment, the anti-polarization layer 102 may strengthen the RESURF structure for further reducing current collapse and/or threshold hysteresis. In some embodiments, the anti-polarization layer 102 and the barrier layer 105 may include III-nitride material of the same atomic composition. The thickness of the anti-polarization layer 102 is substantially the same as the thickness of the barrier layer 105 with a tolerance of ±25% in consideration of the feasibility process of the variation control. At this time, the nitride semiconductor layer 110 is completed on the channel layer 103.

Next, as shown in FIG. 3F, an AlN anode dielectric layer 220 is formed on the top surface 110a of the nitride semiconductor layer 110. The AlN anode dielectric layer 220 may be formed by utilizing a process, for example, molecule beam epitaxy (MBE), metal-organic chemical vapor deposition (MOCVD), hydride vapor phase deposition (HVPE), atomic layer deposition (ALD), and plasma-enhanced ALD (PEALD). According to an embodiment, the AlN anode dielectric layer 220 has a thickness ranging between 0.5 nm and 50 nm, but is not limited thereto.

Next, as shown in FIG. 3G, a fluorine treatment is performed to form a fluorinated region 280 in the AlN anode dielectric layer 220. According to an embodiment, the fluorinated region 280 extends into the nitride semiconductor layer 110 and is disposed directly below the anode metal layer 250.

With the fluorine flux energy and the processing time, the fluorine may penetrate into the barrier layer 105, the spacer layer 104, the channel layer 103, or, in other embodiments, deeper into the buffer layer 101. Consequently, the fluorinated region 280 may include at least a portion of AlN layer 220, barrier layer 105, spacer layer 104, channel layer 103, but is not limited thereto.

According to an embodiment, an overlapping region between the AlN anode dielectric layer 220 and the fluorinated region 280 may include N—F atomic bonding and Al—F atomic bonding. According to an embodiment, the formation an N—F atomic bonding may enhance the thermal stability of fluorine and the formation of Al—F atomic bonding may enhance the incorporation of fluorine in the AlN anode dielectric layer 220.

According to an embodiment, the AlN anode dielectric layer 220 has a fluorine concentration that is greater than or equal to 1E21 atoms/cm³.

For example, the fluorine treatment for forming the fluorinated region may be performed in one of the following tools: inductor-coupled plasma (ICP), reactive ion etching (RIE), RIE-ICP, ICP-RIE, capacitor-coupled etch (CCP), transformer-coupled etching (TCP), electron cyclotron resonance (ECR), atomic layer deposition (ALD), chemical vapor deposition (CVD), plasma-enhanced CVD (PECVD), low-pressure CVD (LPCVD), physical vapor deposition (PVD), ion implantor.

As shown in FIG. 3H, a first dielectric protection layer 240a is conformally deposited on the AlN anode dielectric layer 220, and the AlN anode dielectric layer 220 is totally covered with the first dielectric protection layer 240a.

Next, as shown in FIG. 3I, an anode metal layer 250 is formed on the first dielectric protection layer 240a and is disposed directly above the fluorinated region 280.

According to an embodiment, the anode metal layer 250 may include TiN, TiN/Cu, Ti/TaN, Ta/TaN, TiN/Ti/Al/Ti/TiN, Ti, W, TiW, or a combination thereof. For example, the anode metal layer 250 may be composed by TiN or a metal stack structure composed of TiN as a first layer (in direct contact with the first dielectric protection layer 240a) The TiN can effectively suppress the out-diffusion of fluorine.

For example, in some embodiments, the anode metal layer 250 may be a stack structure including titanium nitride/titanium/aluminum/titanium/titanium nitride. The stack structure maintains a certain thickness while reducing the stress in the metal stack. In some further embodiments, after forming the titanium nitride or titanium nitride/titanium/aluminum/titanium/titanium nitride stack, then other metals may be stacked, or further process may be performed, for example, metallization, electrical connection of the elements and/or reducing anode resistance.

Next, as shown in FIG. 3J, a second dielectric protection layer 240b is conformally deposited on the first dielectric protection layer 240a and the anode metal layer 250.

Next, as shown in FIG. 3K, an opening 220a and an opening 220b are formed in the second dielectric protection layer 240b, the first dielectric protection layer 240a and AlN anode dielectric layer 220 by a lithography and etching process, in which the opening 220a and the opening 220b respectively exposed a portion of a top surface 110a of the nitride semiconductor layer 110 predetermined contacting with the cathode electrode (take HEMT as an example, including source electrode and drain electrode).

Next, as shown in FIG. 3L, a source electrode 231 and a drain electrode 232 are formed respectively in the opening 220a and the opening 220b by an e-gun evaporator or sputter.

According to an embodiment, the first dielectric protection layer 240a and the second dielectric protection layer 240b may be formed by atomic layer deposition (ALD), plasma-enhanced ALD (PEALD), chemical vapor deposition (CVD), plasma-enhanced CVD (PECVD), low-pressure CVD (LPCVD).

Next, as shown in FIG. 3M, a dielectric passivation layer 260 is covered the anode metal layer 250 and the second dielectric protection layer 240b by chemical vapor deposition (CVD), plasma-enhanced CVD (PECVD) or low-pressure CVD (LPCVD). According to an embodiment, the dielectric passivation layer 260 may include AlN, Al₂O₃, SiN, SiO₂, ZrO, HfO₂, La₂O₃, Lu₂O₃, LaLuO₃, C₄F₈, or a combination thereof.

The present invention further discloses a method for forming a reduced surface field (RESURF) region in an electron device, by extending the fluorinated anode dielectric to cover the access region and/or the cathode region. In some embodiments related to the method, the negatively charged fluorine atoms may accumulate at a surface of the anode region, extend to the access/cathode region, and/or penetrate to the semiconductor region.

The method may further include an advanced fluorine distribution, by performing at least a fluorine treatment with different energy and/or various dosages in an anode region, a cathode region, and/or an access region.

In some embodiments related to the method, the negatively charged fluorine atoms may accumulate at a surface of the anode region, extend to the access/cathode region, and/or penetrate to the semiconductor region, with varying concentration of fluorine among these regions.

The RESURF region can reduce current collapse and/or to reduce threshold/forward voltage hysteresis. The RESURF region is formed by performing the fluorine treatment with different energy and/or various dosages in the anode region, access region, and/or cathode region.

In some embodiments of the related method, the negatively charged fluorine atoms may accumulate at the surface of the anode region, extend to the access/anode region with varying fluorine concentration, or penetrate to the barrier layer and/or the channel layer. In some embodiments of the method, the RESURF region may be an extension from the dielectric to the semiconductor during the fluorine treatment.

A breakdown voltage of the electron device can be enhanced if the free carriers in a drift region or an access region are depleted or compensated when the critical field is reached. For HEMT/SBD device at off-state, the positive charges are built up in the access region to support the off-state voltage. Hence, by disposing the negatively charged fluorine ions over the access region to form a RESURF region, the 2DEG can be depleted more effectively at off-state to enhance the breakdown voltage. On the other hand, since the AlN dielectric is a polar material that induces huge positive polarization layer at the AlN/nitride interface, the native surface field is quite large.

By employing the fluorinated anode structure and extending it to the access region, the surface field can be reduced to enhance breakdown voltage. Moreover, the fluorinated anode structure extending to the access region may reshape the distribution of electronic field, suppressing the current collapse phenomenon in nitride HEMT/SBD device.

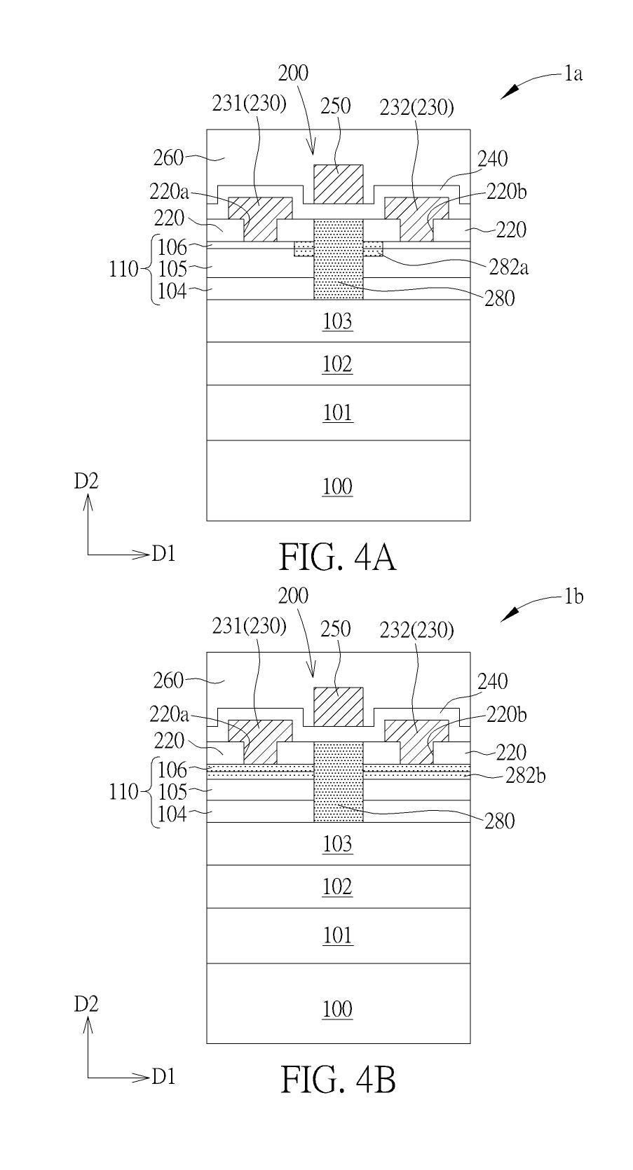

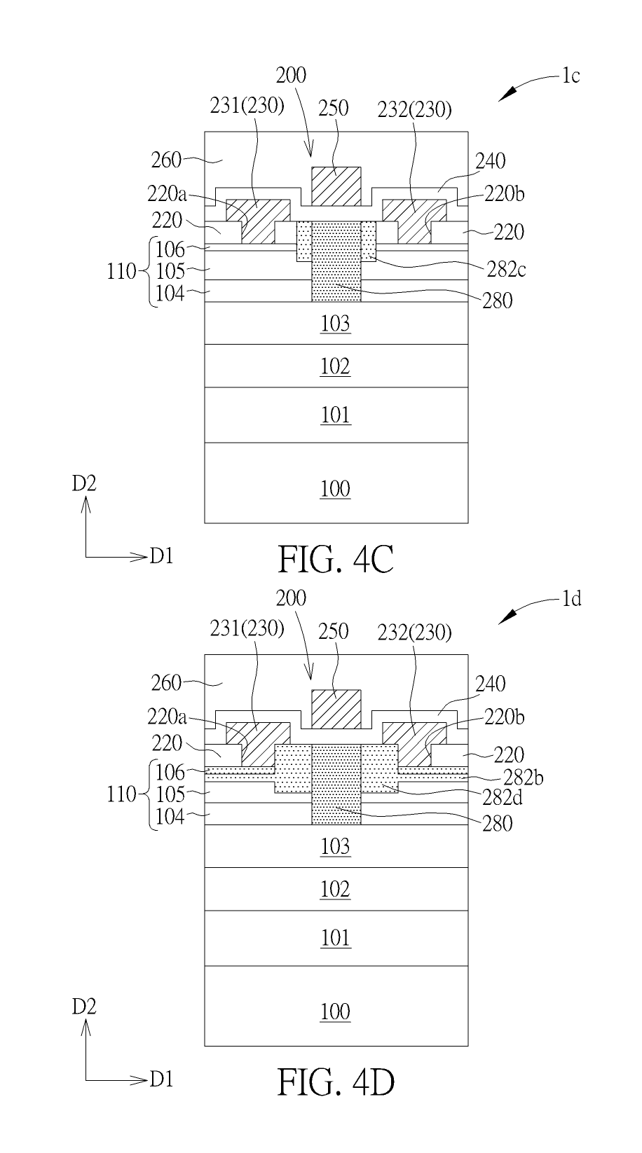

FIG. 4A to 4D are schematic, cross-sectional diagrams of a nitride semiconductor device with a reduced surface field (RESURF) region according to other embodiments of the present invention. The same layers, regions, or elements are still represented by the same numeral numbers.

As shown in FIG. 4A, the nitride semiconductor device 1a has a RESURF region 282a formed at the interface between the AlN anode dielectric layer 220 and the barrier layer 105 by a fluorine treatment. The RESURF region 282a is contiguous with the fluorinated region 280 disposed directly below the anode metal layer 250, and outwardly extends a predetermined distance along the first direction D1, but the distance does not reach a region directly below the source electrode 231 and the drain electrode 232. According to an embodiment, the RESURF region 282a may be slightly diffused into a portion of the AlN anode dielectric layer 220. The RESURF region 282a may cover a portion of the cap layer 106.

As shown in FIG. 4B, the nitride semiconductor device 1b has a RESURF region 282b formed at the interface between the AlN anode dielectric layer 220 and the barrier layer 105 by a fluorine treatment. The RESURF region 282b is contiguous with the fluorinated region 280 disposed directly below the anode metal layer 250. The difference from FIG. 4A is that the RESURF region 282b of the nitride semiconductor device 1b extends outwardly along the first direction D1 to cover the entire AlN anode dielectric layer 220.

As shown in FIG. 4C, the nitride semiconductor device 1c has a RESURF region 282c formed in the AlN anode dielectric layer 220 and the barrier layer 105 by a fluorine treatment The RESURF region 282c is contiguous with the fluorinated region 280 disposed directly below the anode metal layer 250. The difference from FIG. 4A is that the RESURF region 282c of the nitride semiconductor device 1c extends along the second direction D2 to cover the entire AlN anode dielectric layer 220.

As shown in FIG. 4D, the nitride semiconductor device 1d has a RESURF region 282d and the RESURF region 282b as shown in FIG. 4D formed in the AlN anode dielectric layer 220 and the barrier layer 105 by a fluorine treatment. The RESURF regions 282b and 282d are contiguous with the fluorinated region 280 disposed directly below the anode metal layer 250. The range of the RESURF region 282d extends in the first direction D1 and the second direction D2 to cover the entire AlN anode dielectric layer 220 between the fluorinated region 280 and the source electrode 231 and between the fluorinated region 280 and the drain electrode 232.

In other embodiments, the fluorine treatment may include a doping effect and an etching effect while generating a recess region in the HEMT/SBD device. In some embodiments, the fluorinated region 280 features of the present invention may be introduced into the recess region and the anode region.

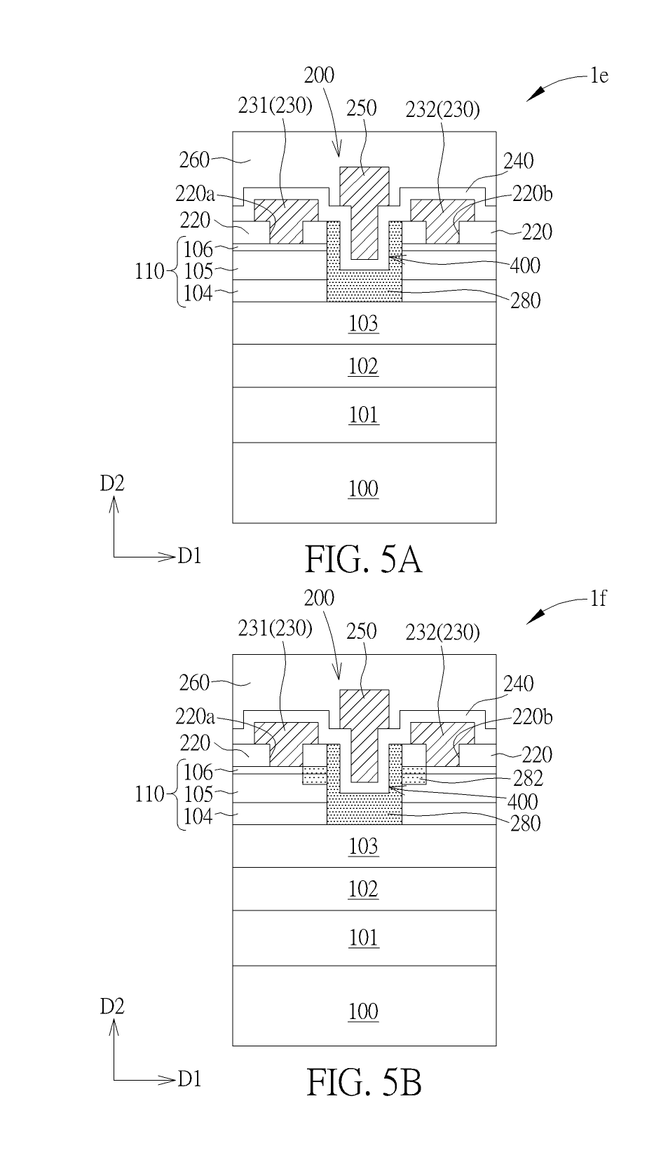

FIG. 5A to 5B are schematic, cross-sectional diagrams of a nitride semiconductor device with a recess region according to other embodiments of the present invention. The same layers, regions, or elements are still represented by the same numeral numbers.

As shown in FIG. 5A, a recess region 400 may be formed in the nitride semiconductor device 1e before, after, or during formation of the fluorinated anode structure 200. The recess region 400 is recessed into the nitride semiconductor layer 110. In some embodiments, the recess region 400 may penetrate into the spacer layer 104 or the channel layer 103 in the second direction D2. The dielectric protection layer 240 conformally covers the inner wall of the recess region 400 and the anode metal layer 250 is filled into the recess region 400.

In some embodiments, a width of the recess region 400 in the first direction D1 may be less than, greater than, or equal to a width of the fluorinated region 200 in the first direction D1 depending on the incorporation traces of fluorine in the fluorine treatment.

As shown in FIG. 5B, similarly, a recess region 400 is formed in the nitride semiconductor device if. The nitride semiconductor device if differs from the nitride semiconductor device 1e in FIG. 5A in that the nitride semiconductor device if in FIG. 5B further includes an extended fluorinated region 282 that is contiguous with the fluorinated region 280 and is disposed in the barrier layer 105 and the cap layer 106 in some embodiments.

In other embodiments, the nitride semiconductor device may further include an AlN interlayer layer disposed at least in the barrier layer 105 as a fluorine-enhancement layer for increasing the fluorine concentration of the fluorinated anode structure. The AlN interlayer layer may be seen as reinforcement and/or an extension of the AlN anode dielectric layer to further enhance the fluorine concentration or stability.

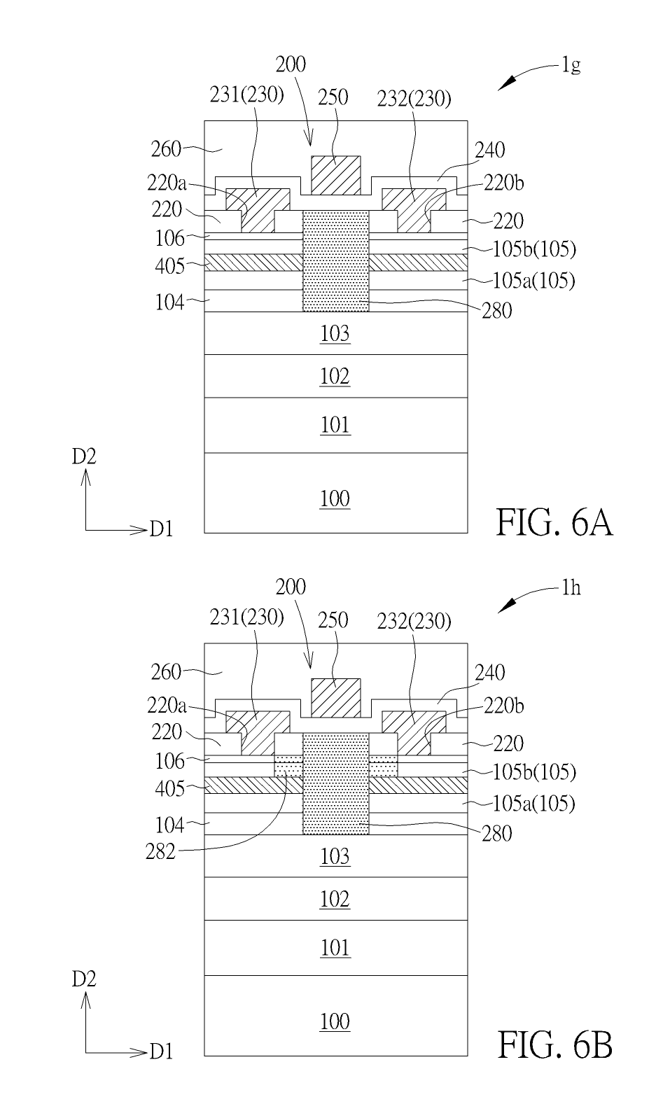

FIG. 6A to 6B are schematic, cross-sectional diagrams of a nitride semiconductor device with an AlN interlayer according to other embodiments of the present invention. The same layers, regions, or elements are still represented by the same numeral numbers.

As shown in FIG. 6A, an AlN interlayer layer 405 is formed in the barrier layer 105 as a fluorine-enhancement layer. In this embodiment, the barrier layer 105 may be divided into a lower barrier layer 105a and an upper barrier layer 105b The AlN interlayer layer 405 may be sandwiched between the lower barrier layer 105a and the upper barrier layer 105b.

Moreover, the AlN interlayer 405 may be used as an etching-stop layer to improve the depth uniformity of the recess region and improve the process window and the threshold/forward voltage of HEMT/SBD device. In some embodiments, the AlN interlayer 405 also may reduce the penetration depth of fluorine.

As shown in FIG. 6B, the nitride semiconductor device 1h also has an AlN interlayer 405 in the barrier layer 105 as a fluorine-enhancement layer and further includes an extended fluorinated region 282 that is contiguous with the fluorinated region 280.

In other embodiments, the nitride semiconductor device may further incorporate the recess region feature in addition to the AlN interlayer disposed in the barrier layer 105.

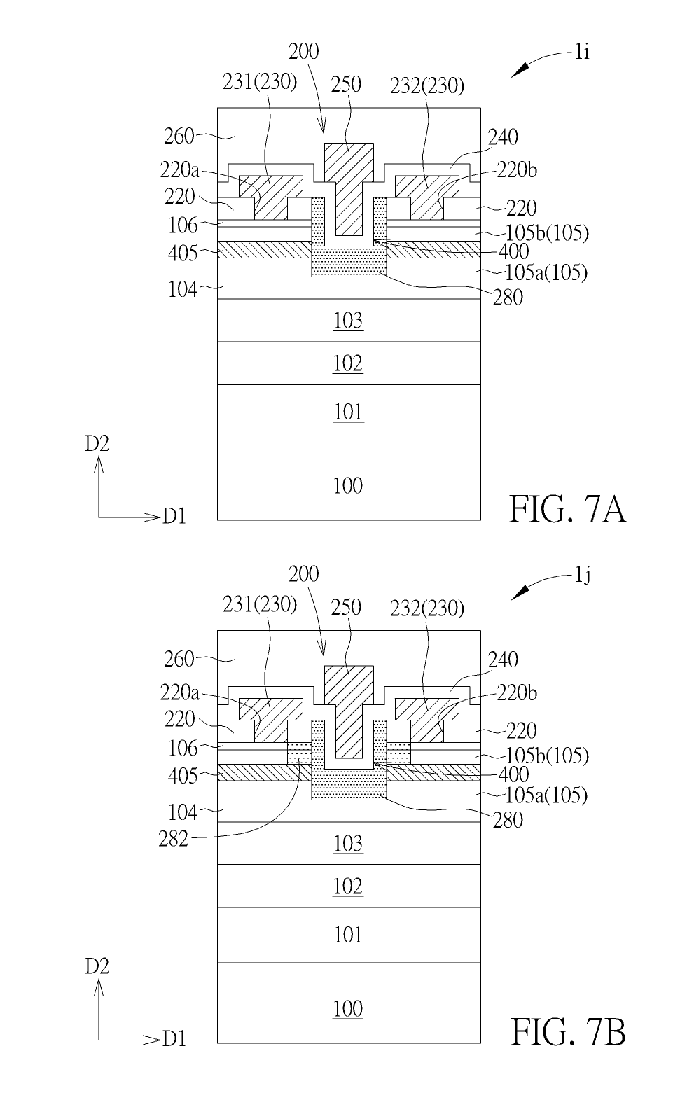

FIG. 7A to 7B are schematic, cross-sectional diagrams of a nitride semiconductor device with a recess region and an AlN interlayer according to other embodiments of the present invention. The same layers, regions, or elements are still represented by the same numeral numbers.

As shown in FIG. 7A, the nitride semiconductor device 1i is formed with an AlN interlayer 405 as a fluorine-enhancement layer in the barrier layer 105. In this embodiment, the recess region 400 is further incorporated. The bottom of the recess region 400 may be stopped at the AlN interlayer 405.

As shown in FIG. 7B, the nitride semiconductor device 1j is formed with an AlN interlayer 405 as a fluorine-enhancement layer in the barrier layer 105. In this embodiment, in addition to further incorporating the recess region 400, an extended fluorinated region 282 is further disposed in the barrier layer 105. The extended fluorinated region 282 is contiguous with the fluorinated region 280.

In general, the nitride semiconductor device of the present invention may be used as a HEMT device, which is capable of achieving the following physical characteristics: drain current ≥1.2 A/mm; threshold voltage ≥2.5V for normally-off devices, ≥−6.5V for normally-on devices; transconductance ≥100 mS/mm; gate leakage current ≤1E-10 A/mm; breakdown voltage ≥1200V; and threshold hysteresis ≤0.1V.

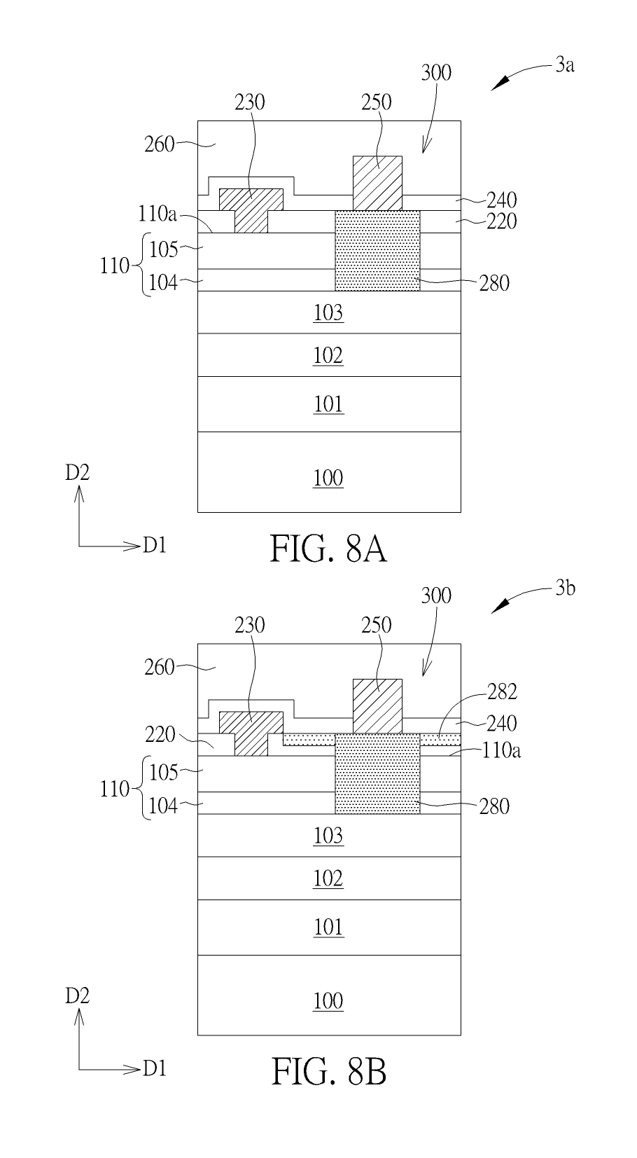

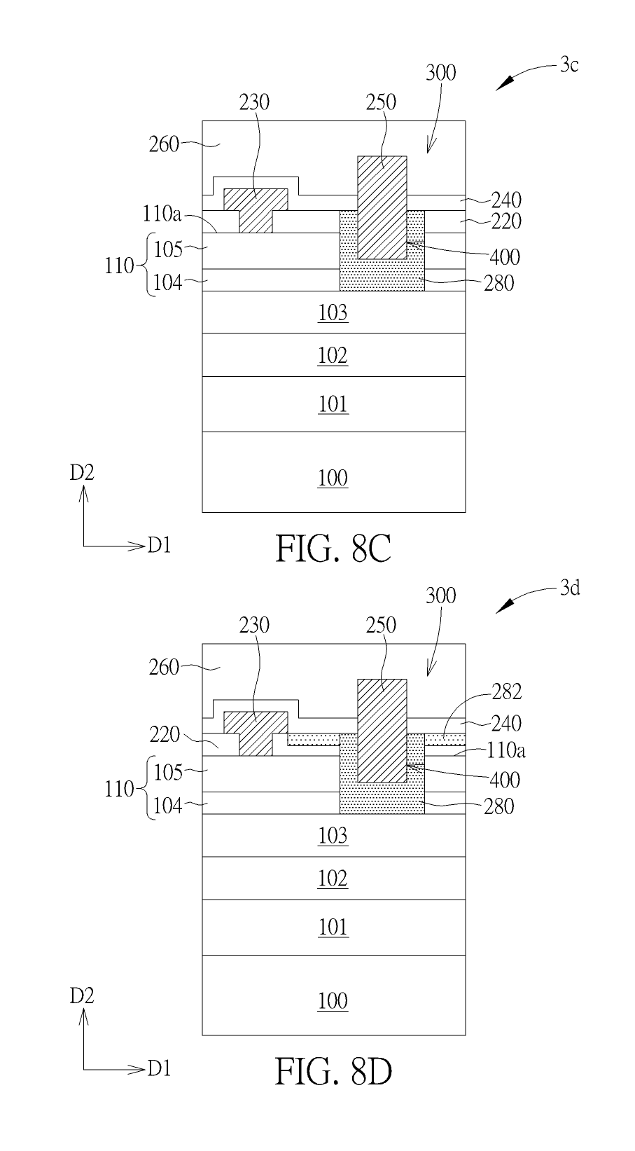

The nitride semiconductor device of the present invention may also be used as a Schottky Barrier Diodes (SBD). FIG. 8A to 8D illustrate four kinds of nitride semiconductor devices as Schottky barrier diodes, respectively. The same layers, regions, or elements are still represented by the same numeral numbers.

As shown in FIG. 8A, a nitride compound semiconductor device 3a includes a substrate 100 including a silicon substrate, silicon carbide (SiC) substrate, sapphire substrate, gallium nitride (GaN) substrate, or aluminum nitride (AlN) substrate. A buffer layer 101, for example, GaN, AlGaN, AlInN, AlGaInN or AlN, but is not limited thereto, is formed on the substrate 100. An anti-polarization layer (APL) 102 is formed on the buffer layer 101. The APL 102 may include AlGaN, AlInN, AlGaInN, AlN, or a combination thereof. A channel layer 103 is formed on the APL 102. The channel layer 103 may include GaN, AlGaN, AlInN, InGaN, AlGaInN, or a combination thereof.

According to an embodiment, a nitride semiconductor layer 110 is formed on the channel layer 103. According to an embodiment, for example, the nitride semiconductor layer 110 may include a barrier layer 105 on the channel layer 103, and a spacer layer 104 between the barrier layer 105 and the channel layer 103. The barrier layer 105 may include AlGaN, AlInN, AlGaInN, AlN or a combination thereof. For example, the spacer layer 104 may include AlN.

According to an embodiment, the barrier layer 105 is preferably AlGaN, which can retain 2-dimensional electron gas (2DEG) in the nitride HEMT/SBD device. In order to further increase the 2DEG density and mobility, an AlInN, an AlInGaN, or an AlN barrier layer may be introduced due to their relatively large polarization charge, thereby increasing the current density. However, a large amount of polarization charge in the anode region reduces the breakdown voltage of the SBD device. On the other hand, since the energy band gap is relatively large, the forward voltage of the device is too high, reducing the conversion efficiency of the device on the circuit. The above problem may be overcome by incorporating the fluorinated anode structure.

According to an embodiment, a material of the anti-polarization layer 102 is the same as a material of the barrier layer 105. According to an embodiment, a material of the anti-polarization layer 102 is the same as a material of the barrier layer 105. According to an embodiment, the anti-polarization layer 102 may strengthen the RESURF structure for further reducing current collapse and/or threshold hysteresis. In some embodiments, the anti-polarization layer 102 and the barrier layer 105 may include III-nitride material of the same atomic composition. The thickness of the anti-polarization layer 102 is substantially the same as the thickness of the barrier layer 105 with a tolerance of ±25% in consideration of the feasibility process of the variation control.

According to an embodiment, a fluorinated anode structure 300 is disposed on a top surface 110a of the nitride semiconductor layer 110. According to an embodiment, the fluorinated anode structure 300 includes an AlN anode dielectric layer 220 on the top surface 110a of the nitride semiconductor layer 110, a fluorinated region 280 disposed in the AlN anode dielectric layer 220, and an anode metal layer 250 disposed on the AlN anode dielectric layer 220.

According to an embodiment, the fluorinated region 280 may be formed by a fluorine treatment before forming the anode metal layer 250. For example, it may be formed by surface plasma treatment, atomic layer deposition (ALD), chemical vapor deposition (CVD), or ion implantation with lithography process.

According to an embodiment, the nitride compound semiconductor device 3a further includes a cathode structure 230. The cathode structure 230 is disposed together with the anode metal layer 250 on the top surface 110a of the nitride semiconductor layer 110 in a first direction D1. According to an embodiment, the cathode structure 230 is in proximity to the fluorinated anode structure 200 in the first direction D1.

According to an embodiment, the cathode structure 230 and is kept at a predetermined distance from the anode metal layer 250 and are electrically isolated from the anode metal layer 250 through a dielectric protection layer 240. According to an embodiment, the dielectric protection layer 240 covers the cathode structure 230 and the AlN anode dielectric layer 220 in the first direction D1. According to an embodiment, the anode metal layer 250 is extended through the dielectric protection layer 240 and is in direct contact with the AlN anode dielectric layer 220.

As shown in FIG. 8B, the difference between the nitride semiconductor device 3b and the nitride semiconductor device 3a is that the nitride semiconductor device 3b further incorporates an extended fluorinated region 282 that is contiguous with the fluorinated region 280 and is disposed in the AlN anode dielectric layer 220.

As shown in FIG. 8C, the difference between the nitride semiconductor device 3c and the nitride semiconductor device 3a is that the nitride semiconductor device 3c further incorporates a recess region 400.

As shown in FIG. 8D, the difference between the nitride semiconductor device 3d and the nitride semiconductor device 3a is that the nitride semiconductor device 3d further incorporates the extended fluorinated region 282 disposed in the AlN anode dielectric layer 220 in addition to further incorporating the recess region 400. The extended fluorinated region 282 is contiguous with the fluorinated region 280.

In general, the nitride semiconductor device of the present invention is used as a SBD device, which achieves the following physical characteristics: forward voltage ≤1.5V; drain current ≤1E-6 A/mm; and breakdown voltage ≥1200V.

Those skilled in the art will readily observe that numerous modifications and alterations of the device and method may be made while retaining the teachings of the invention. Accordingly, the above disclosure should be construed as limited only by the metes and bounds of the appended claims.

1. A high electron mobility transistor, comprising:
a substrate;
a channel layer disposed on the substrate;
a nitride semiconductor layer disposed on the channel layer;
a fluorinated anode structure disposed on the nitride semiconductor layer,
wherein the fluorinated anode structure comprises an AlN anode dielectric layer on the nitride semiconductor layer, a fluorinated region in the AlN anode dielectric layer, and an anode metal layer disposed on the AlN anode dielectric layer, wherein an overlapping region between the AlN anode dielectric layer and the fluorinated region comprises atomic bonding of AlFₓ and atomic bonding of NFₓ; and
a cathode structure disposed on the nitride semiconductor layer and in proximity to the fluorinated anode structure.

2-3. (canceled)

4. The high electron mobility transistor according to claim 1, wherein the anode metal layer comprises TiN, TiN/Cu, Ti/TaN, Ta/TaN, TiN/Ti/Al/Ti/TiN, Ti, W, TiW, or a combination thereof.

5. The high electron mobility transistor according to claim 1, wherein the fluorinated region extends into the nitride semiconductor layer and the fluorinated region is situated directly under the anode metal layer.

6. The high electron mobility transistor according to claim 1 further comprising an extended fluorinated region that is contiguous with the fluorinated region.

7. The high electron mobility transistor according to claim 1, wherein the nitride semiconductor layer comprises a barrier layer on the channel layer, and a spacer layer between the barrier layer and the channel layer.

8. The high electron mobility transistor according to claim 7, wherein the channel layer comprises GaN, AlGaN, AlInN, InGaN, AlGaInN, or a combination thereof.

9. The high electron mobility transistor according to claim 8, wherein the barrier layer comprises AlGaN, AlInN, AlInGaN, AlN, or a combination thereof.

10. The high electron mobility transistor according to claim 9, wherein the spacer layer comprises AlN.

11. The high electron mobility transistor according to claim 1, wherein the substrate comprises a silicon substrate, a silicon carbide (SiC) substrate, a sapphire substrate, a gallium nitride (GaN) substrate, or an aluminum nitride (AlN) substrate.

12. The high electron mobility transistor according to claim 1, wherein the AlN anode dielectric layer has a thickness ranging between 0.5 nm and 50 nm.

13. The high electron mobility transistor according to claim 1, wherein the AlN anode dielectric layer has a fluorine concentration that is greater than or equal to 1E21 atoms/cm³.

14. The high electron mobility transistor according to claim 1, wherein the cathode structure comprises a source electrode and a drain electrode disposed on the nitride semiconductor layer.

15. The high electron mobility transistor according to claim 14 further comprising a dielectric protection layer disposed between the anode metal layer and the AlN anode dielectric layer.

16. The high electron mobility transistor according to claim 15, wherein the dielectric protection layer covers the source electrode and the drain electrode.

17. The high electron mobility transistor according to claim 15, wherein the dielectric protection layer comprises AlN, Al₂O₃, SiN, SiO₂, ZrO, HfO₂, La₂O₃, Lu₂O₃, LaLuO₃, C₄F₈, or a combination thereof.

18. The high electron mobility transistor according to claim 1 further comprising a buffer layer between the channel layer and the substrate.

19. The high electron mobility transistor according to claim 15, wherein the buffer layer comprises GaN, AlGaN, AlInN, AlGaInN or AlN.

20. The high electron mobility transistor according to claim 18 further comprising an anti-polarization layer between the channel layer and the buffer layer.

21. The high electron mobility transistor according to claim 20, wherein the anti-polarization layer comprises AlGaN, AlInN, AlGaInN, AlN, or a combination thereof.

22. The high electron mobility transistor according to claim 15, further comprising a dielectric passivation layer covering the anode metal layer and the dielectric protection layer.

23. The high electron mobility transistor according to claim 20, wherein the dielectric passivation layer comprises AlN, Al₂O₃, SiN, SiO₂, ZrO, HfO₂, La₂O₃, Lu₂O₃, LaLuO₃, C₄F₈, or a combination thereof.

24. The high electron mobility transistor according to claim 1 further comprising an AlN interlayer in the barrier layer to enhance the fluorine concentration in the fluorinated anode structure.

25. The high electron mobility transistor according to claim 1, wherein the fluorinated anode structure further comprises a recess region recessed into the nitride semiconductor layer, wherein the anode metal layer fills into the recess region.

26. The high electron mobility transistor according to claim 1 further comprising a cap layer between the nitride semiconductor layer and the AlN anode dielectric layer.

27. The high electron mobility transistor according to claim 26, wherein the cap layer comprises GaN, AlGaN, AlInN, InGaN, AlGaInN, SiN, or a combination thereof.

28. A high electron mobility transistor, comprising:
a substrate;
a channel layer disposed on the substrate;
a nitride semiconductor layer disposed on the channel layer;
a fluorinated anode structure disposed on the nitride semiconductor layer, wherein the fluorinated anode structure comprises an AlN anode dielectric layer on the nitride semiconductor layer, a GaN cap layer on the AlN anode dielectric layer, a fluorinated region in the AlN anode dielectric layer and the GaN cap layer, and an anode metal layer disposed on the GaN cap layer; and
a cathode structure disposed on the nitride semiconductor layer and in proximity to the fluorinated anode structure.

29. A high electron mobility transistor, comprising:
a substrate;
a channel layer disposed on the substrate;
a nitride semiconductor layer disposed on the channel layer;
a fluorinated anode structure disposed on the nitride semiconductor layer, wherein the fluorinated anode structure comprises an AlN anode dielectric layer on the nitride semiconductor layer, a SiN cap layer on the AlN anode dielectric layer, a fluorinated region in the AlN anode dielectric layer and the SiN cap layer, and an anode metal layer disposed on the SiN cap layer; and
a cathode structure disposed on the nitride semiconductor layer and in proximity to the fluorinated anode structure.

30. A nitride semiconductor device, comprising:
a substrate;
a nitride semiconductor layer disposed on the substrate;
an AlN anode dielectric layer disposed on the nitride semiconductor layer;
an anode metal layer disposed on the AlN anode dielectric layer; and
a fluorinated region disposed in the AlN anode dielectric layer and extending into the nitride semiconductor layer, wherein an overlapping region between the AlN anode dielectric layer and the fluorinated region comprises atomic bonding of AlFₓ and atomic bonding of NFₓ.

31-32. (canceled)

33. The nitride semiconductor device according to claim 30, wherein the AlN anode dielectric layer has a thickness ranging between 0.5 nm and 50 nm.

34. The nitride semiconductor device according to claim 30, wherein the AlN anode dielectric layer has a fluorine concentration that is greater than or equal to 1E21 atoms/cm³.
